(19) United States
(12) Patent Application Publication
(10) Pub. No.: US 2026/0190791 A1
(43) Pub. Date: Jul. 2, 2026

(54) DISPLAY DEVICE

(71) Applicant: LG Display Co., Ltd., Seoul (KR)

(72) Inventor: Soobin Bae, Paju-si (KR)

(73) Assignee: LG Display Co., Ltd., Seoul (KR)

(21) Appl. No.: 19/217,159

(22) Filed: May 23, 2025

(30) Foreign Application Priority Data
Dec. 30, 2024 (KR) 10-2024-0200488

(51) Int. Cl. H10K 59/80; H10K 59/122; H10K 59/131; H10K 59/40

(52) U.S. Cl. CPC H10K 59/8731; H10K 59/122; H10K 59/131; H10K 59/40

(57) ABSTRACT

A display device, in one or more examples, may include a substrate, a display area where an image is displayed, a non-display area, an insulation layer extending from the display area to the non-display area and disposed on the substrate, a light emitting element positioned in the display area and disposed on the insulation layer, an outer bank positioned in the non-display area and disposed to cover an end portion of the insulation layer, an encapsulation layer disposed on the light emitting element and extending from the display area to the non-display area, a touch buffer layer disposed on the encapsulation layer, and a touch metal disposed on the touch buffer layer. The touch buffer layer may extend from the display area to the non-display area and extend to an outer area of the encapsulation layer to have a trench positioned in the outer area of the encapsulation layer.

### CROSS-REFERENCE TO RELATED APPLICATION

This application claims the benefit of and priority to Korean Patent Application No. 10-2024-0200488, filed on Dec. 30, 2024, the entire contents of which are incorporated herein by reference for all purposes as if fully set forth herein.

### BACKGROUND

### 1. Technical Field

Embodiments of the disclosure relate to a display device.

### 2. Description of Related Art

As the information society develops, demand for display devices for displaying images is increasing in various forms. Various display devices, such as liquid crystal display devices and organic light emitting display devices, are being utilized in recent years.

Further, research on various display devices such as flexible, bendable, stretchable, and rollable, which are applicable to small wearable electronic devices, is also actively underway.

However, in these flexible, bendable, stretchable, and rollable display devices, issues such as cracks and delamination at the edge may occur during the laser trimming of the display panel, which includes specific areas such as bending, stretching, and rolling areas.

The description of related art should not be considered prior art merely because it is mentioned in or associated with this section. The description of related art includes information that describes one or more aspects of the subject technology, and the description in this section does not limit the scope of the invention.

### SUMMARY

Embodiments of the disclosure may provide a display device that minimizes the effects caused by cracks and delamination at the edge portion of the display panel.

Embodiments of the disclosure may provide a display device that may block moisture ingress paths caused by the delamination of the touch buffer layer.

Aspects of the disclosure are not limited to those set forth herein, and other unmentioned aspects would be apparent to one of ordinary skill in the art from the following description.

Embodiments of the disclosure may provide a display device comprising a substrate, a display area where an image is displayed, a non-display area positioned outside the display area, an insulation layer extending from the display area to the non-display area and disposed on the substrate, a light emitting element positioned in the display area and disposed on the insulation layer, an outer bank positioned in the non-display area and disposed to cover an end portion of the insulation layer, an encapsulation layer disposed on the light emitting element and extending from the display area to the non-display area, a touch buffer layer disposed on the encapsulation layer, and a touch metal disposed on the touch buffer layer, wherein the touch buffer layer extends from the display area to the non-display area and extends to an outer area of the encapsulation layer to have a trench positioned in the outer area of the encapsulation layer.

Embodiments of the disclosure may provide a display device comprising a substrate, a display area where an image is displayed, a non-display area positioned outside the display area, an insulation layer extending from the display area to the non-display area and disposed on the substrate, a light emitting element positioned in the display area and disposed on the insulation layer, an outer bank positioned in the non-display area and disposed to cover an end portion of the insulation layer, an encapsulation layer disposed on the light emitting element and extending from the display area to the non-display area, a touch buffer layer disposed on the encapsulation layer, a touch metal disposed on the touch buffer layer, and a touch protective layer disposed on the touch metal and extending from the display area to the non-display area, wherein the touch protective layer covers an edge of the touch buffer layer and contacts an upper surface of the substrate, outside the touch buffer layer.

According to embodiments of the disclosure, there may be provided a display device that minimizes the effects caused by cracks and delamination at the edge portion of the display panel.

According to embodiments of the disclosure, there may be provided a display device capable of minimizing GDS by blocking moisture ingress paths caused by the delamination of the touch buffer layer.

According to embodiments of the disclosure, there may be provided a display device capable of low-power driving by minimizing GDS.

The effects of the disclosure are not limited to the foregoing aspects, and other effects will be apparent to one of ordinary skill in the art from the following detailed description.

Additional features, advantages, and aspects of the present disclosure are set forth in part in the description that follows and in part will become apparent from the present disclosure or may be learned by practice of the inventive concepts provided herein. Other features, advantages, and aspects of the present disclosure may be realized and attained by the descriptions provided in the present disclosure, or derivable therefrom, and the claims hereof as well as the drawings. It is intended that all such features, advantages, and aspects be included within this description, be within the scope of the present disclosure, and be protected by the following claims. Nothing in this section should be taken as a limitation on those claims. Further aspects and advantages are discussed below in conjunction with embodiments of the present disclosure.

It is to be understood that both the foregoing description and the following description of the present disclosure are examples, and are intended to provide further explanation of the disclosure as claimed.

### BRIEF DESCRIPTION OF THE DRAWINGS

The accompanying drawings, which are included to provide a further understanding of the present disclosure, are incorporated in and constitute a part of this present disclosure, illustrate aspects and embodiments of the present disclosure, and together with the description serve to explain principles and examples of the disclosure. In the drawings:

FIG. 1 is a perspective view illustrating a display device according to embodiments of the disclosure;

FIG. 2 is a view illustrating an example structure in which a touch screen panel is embedded in a display panel of a display device according to embodiments of the disclosure;

FIG. 3 is a view illustrating a bending structure and a wiring structure in a planar structure of a display panel according to embodiments of the disclosure;

FIGS. 4 to 6 are views illustrating a cross-sectional structure of a display panel according to embodiments of the disclosure;

FIG. 7 is a view illustrating a cross-sectional structure of a display panel according to embodiments of the disclosure;

FIG. 8 is a view illustrating an example of a planar structure of a display panel according to embodiments of the disclosure;

FIGS. 9 and 10 are cross-sectional views taken along line A-A′ of FIG. 8 according to embodiments of the disclosure;

FIG. 11 is a cross-sectional view taken along line B-B′ of FIG. 7 according to embodiments of the present specification; and

FIG. 12 is a view illustrating a cross-sectional structure of a bending area BA according to embodiments of the disclosure.

Throughout the drawings and the detailed description, unless otherwise described, the same drawing reference numerals should be understood to refer to the same elements, features, and structures. The sizes, lengths, and thicknesses of layers, regions and elements, and depiction thereof may be exaggerated for clarity, illustration, and/or convenience.

### DETAILED DESCRIPTION

In the following description of examples or embodiments of the disclosure, reference will be made to the accompanying drawings in which it is shown by way of illustration specific examples or embodiments that can be implemented, and in which the same reference numerals and signs can be used to designate the same or like components even when they are shown in different accompanying drawings from one another. Further, in the following description of examples or embodiments of the disclosure, detailed descriptions of well-known functions and components incorporated herein will be omitted when it is determined that the description may make the subject matter in some embodiments of the disclosure rather unclear. The terms such as “including”, “having”, “containing”, “constituting”, “make up of”, and “formed of” used herein are generally intended to allow other components to be added unless the terms are used with the term “only”. As used herein, singular forms are intended to include plural forms unless the context clearly indicates otherwise. For example, an element may be one or more elements. An element may include a plurality of elements. The word “exemplary” is used to mean serving as an example or illustration. Embodiments are example embodiments. Aspects are example aspects. In one or more implementations, “embodiments,” “examples,” “aspects,” and the like should not be construed to be preferred or advantageous over other implementations. An embodiment, an example, an example embodiment, an aspect, or the like may refer to one or more embodiments, one or more examples, one or more example embodiments, one or more aspects, or the like, unless stated otherwise.

Terms, such as “first”, “second”, “A”, “B”, “(A)”, or “(B)” may be used herein to describe elements of the disclosure. Each of these terms is not used to define essence, order, sequence, or number of elements etc., but is used merely to distinguish the corresponding element from other elements.

When it is mentioned that a first element “is connected or coupled to”, “contacts or overlaps”, etc. a second element, it should be interpreted that, not only can the first element “be directly connected or coupled to” or “directly contact or overlap” the second element, but a third element can also be “interposed” between the first and second elements, or the first and second elements can “be connected or coupled to”, “contact or overlap”, etc. each other via a fourth element. Here, the second element may be included in at least one of two or more elements that “are connected or coupled to”, “contact or overlap”, etc. each other.

When time relative terms, such as “after”, “subsequent to”, “next”, “before”, and the like, are used to describe processes or operations of elements or configurations, or flows or steps in operating, processing, manufacturing methods, these terms may be used to describe non-consecutive or non-sequential processes or operations unless the term “directly” or “immediately” is used together.

In addition, when any dimensions, relative sizes etc. are mentioned, it should be considered that numerical values for an elements or features, or corresponding information (e.g., level, range, etc.) include a tolerance or error range that may be caused by various factors (e.g., process factors, internal or external impact, noise, etc.) even when a relevant description is not specified. Further, the term “may” fully encompasses all the meanings of the term “can”.

Hereinafter, various embodiments of the disclosure are described in detail with reference to the accompanying drawings.

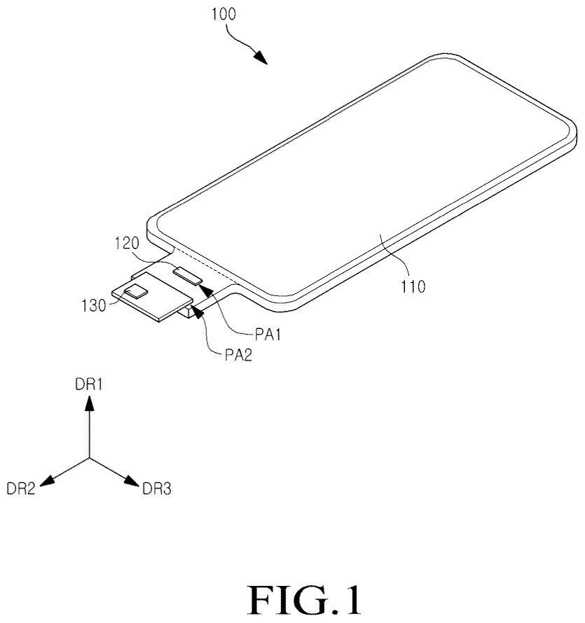

FIG. 1 is a perspective view illustrating a display device 100 according to embodiments of the disclosure.

Referring to FIG. 1, a display device 100 according to embodiments of the disclosure may be applied to portable electronic devices such as a mobile phone, smart phone, tablet personal computer, mobile communication terminal, electronic organizer, electronic book, portable multimedia player (PMP), navigation, and ultra mobile PC (UMPC).

Alternatively, the display device 100 of the disclosure may be applied to televisions, laptops, monitors, signage, or wearable devices such as smart watches or watch phones. The display device 100 of the disclosure may be applied into various vehicle components, including the instrument panel, the center fascia, the center information display (CID) located on the dashboard, a room mirror display substituting for a side mirror, or a rear-seat entertainment display mounted on the back of the front seat.

The display device 100 of the disclosure may be a display device such as an organic light emitting display device using an organic light emitting diode, a quantum dot light emitting display device including a quantum dot light emitting layer, an inorganic light emitting display device including an inorganic semiconductor, and a micro light emitting display device using a micro LED. Hereinafter, although the display device 100 is an organic light emitting display device in an embodiment, the disclosure is not limited thereto.

Referring to FIG. 1, a display device 100 according to embodiments of the disclosure may include a display panel 110 and display driving circuits, as components for displaying images. The display driving circuit may be a circuit for driving the display panel 110. The display driving circuit may include a data driving circuit, a gate driving circuit, a controller, or the like, but embodiments of the disclosure are not limited thereto.

The display device 100 of the disclosure may include a display panel 110, a first pad area PA1, and a second pad area PA2. The first pad area PA1 and the second pad area PA2 may be connected to or bonded with driving circuits, such as the data driving circuit or the gate driving circuit.

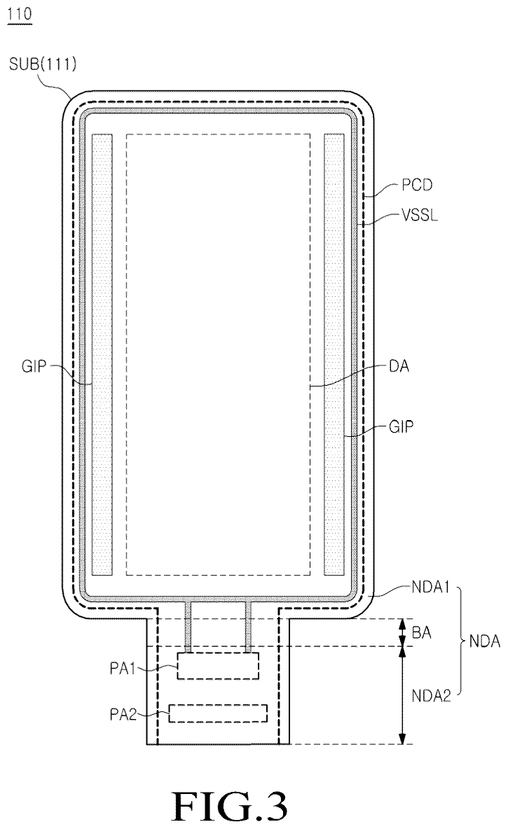

Referring to FIG. 1, the first pad area PA1 and the second pad area PA2 may be positioned on the display panel 110. Referring to FIGS. 1 and 3, the first driver 120 may be disposed in the first pad area PA1. Referring to FIGS. 1 and 3, one end of the circuit unit on which the second driver 130 is disposed may be connected to the second pad area PA2 of the display panel 110.

Referring to FIG. 1, two pad areas PA1 and PA2 are illustrated, but two or more pad areas may be provided. For example, the pad area may be an area positioned at the edge of the substrate. The pad area may be an area on which a chip is mounted. The pad area may be an area where a pad of another substrate or another film is connected to a pad of the substrate of the display panel 100.

The display panel 110 may be formed as a rectangular plane having a short side in a first direction and a long side in a second direction crossing the first direction. The corner where the short side in the first direction and the long side in the second direction meet may be rounded or formed at a right angle to have a predetermined curvature. The planar shape of display panel 110 is not limited to a rectangle and may be formed in another polygonal shape, a circular shape, or an elliptical shape. The display panel 110 may be formed to be flat, but the disclosure is not limited thereto. For example, the display panel 110 is formed at left and right ends and may include a curved portion having a constant curvature or a varying curvature. Further, the display panel 110 may be flexibly formed to be bendable, foldable, or rollable, but the disclosure is not limited thereto.

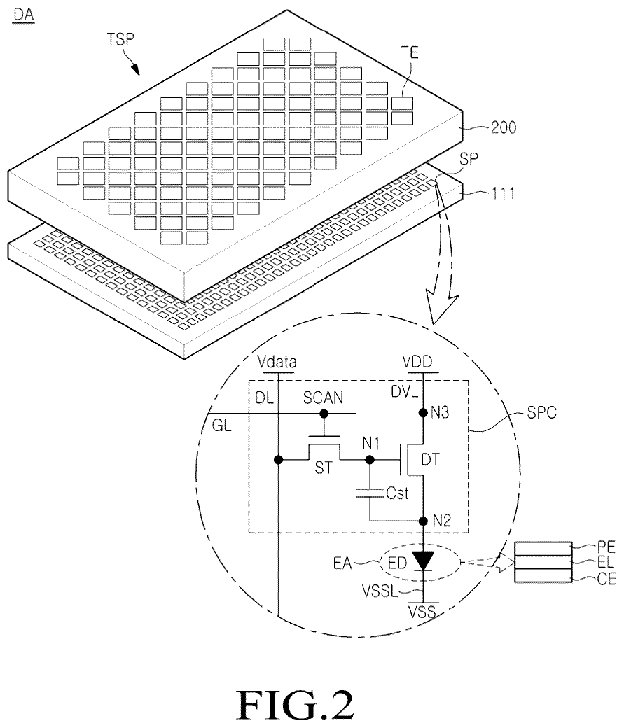

FIG. 2 is a view illustrating an example of a structure in which a touchscreen panel is embedded in a display panel 110 of a display device 100 according to embodiments of the disclosure.

Referring to FIG. 2, a display panel according to embodiments of the disclosure may include a substrate 111 where a plurality of subpixels SP are disposed and an encapsulation layer 200 on the substrate 111. The encapsulation layer 200 may also be referred to as an encapsulation substrate or an encapsulation unit.

The display device 100 according to embodiments of the disclosure may be a self-luminous display device that emits light by itself, but embodiments of the disclosure are not limited thereto. When the display device 100 according to embodiments of the disclosure is a self-luminous display device, each of the plurality of subpixels SP disposed on the substrate 111 may include a light emitting element ED and a subpixel circuit SPC for driving the light emitting element ED.

The subpixel circuit SPC may include a plurality of transistors and at least one capacitor for driving the light emitting element ED, but embodiments of the disclosure are not limited thereto. In the disclosure, the subpixel circuit SPC may drive the light emitting element ED by supplying a driving current to the light emitting element ED at a predetermined timing. The light emitting element ED may be driven by a driving current to emit light.

Various types of signal lines for driving a plurality of subpixels SP may be disposed on the substrate 111 of the display panel 110. For example, various types of signal lines may include a plurality of data lines DL transferring data signals (also referred to as data voltages or image signals) to a plurality of subpixels SP and a plurality of gate lines GL transferring gate signals (also referred to as scan signals) to the plurality of subpixels SP.

The plurality of data lines DL and the plurality of gate lines GL may cross each other. Each of the plurality of gate lines GL may be disposed to extend in a first direction (e.g., row direction or column direction). Each of the plurality of data lines DL may be disposed to extend in a second direction (e.g., a column direction or row direction) different from the first direction.

In embodiments of the disclosure, for example, the first direction may be the row direction, and the second direction may be the column direction. As another example, the first direction may be the column direction, and the second direction may be the row direction. The row direction and the column direction may be relative directions. For example, the column direction may be the row direction depending on the viewpoint, and the row direction may be the column direction depending on the viewpoint. For convenience of description, described below is an example in which each of the plurality of data lines DL is disposed in the column direction, and each of the plurality of gate lines GL is disposed in the row direction, but embodiments of the disclosure are not limited thereto. In embodiments of the disclosure, the angle between the first direction and the second direction may be 90 degrees or may an angle different from 90 degrees.

The data driving circuit 120 may be a circuit for driving the plurality of data lines DL, and may out data signals to the plurality of data lines DL.

The data driving circuit 120 may receive digital image data DATA from the controller and may convert the received image data DATA into analog data signals (or also referred to as data voltages) and output them to the plurality of data lines DL.

For example, the data driving circuit may be connected with the display panel 110 by a tape automated bonding (TAB) method or connected to a bonding pad of the display panel 110 by a chip on glass (COG) or chip on panel (COP) method or may be implemented by a chip on film (COF) method and connected with the display panel 110, but embodiments of the disclosure are not limited thereto.

The data driving circuit may be connected to one side (e.g., an upper or lower side) of the display panel 110. As another example, depending on the driving scheme or the panel design scheme, data driving circuits may be connected with both the sides (e.g., both the upper and lower sides) of the display panel 110, or two or more of the four sides of the display panel 110.

The data driving circuit may be connected outside the display area of the display panel 110, but as another example, the data driving circuit 120 may be disposed in the display area of the display panel 110.

The gate driving circuit is a circuit for driving the plurality of gate lines GL, and may output gate signals to the plurality of gate lines GL.

The gate driving circuit may receive a first gate voltage corresponding to a turn-on voltage (or also referred to as a turn-on level voltage) and a second gate voltage corresponding to a turn-off voltage (or also referred to as a turn-off level voltage) together with various gate driving control signals GCS, generate gate signals including a section having the first gate voltage and a section having the second gate voltage for a predetermined time (e.g., one frame time), and supply the generated gate signals to the plurality of gate lines GL. For example, the turn-on level voltage may be a high level voltage, and the turn-off level voltage may be a low level voltage. As another example, the turn-on level voltage may be a low level voltage, and the turn-off level voltage may be a high level voltage.

In the display device 100 according to embodiments of the disclosure, the gate driving circuit may be embedded, in a gate in panel (GIP) type, in the display panel 110, but embodiments of the disclosure are not limited thereto. When the gate driving circuit is of the gate in panel type, the gate driving circuit may be formed on the substrate 111 of the display panel 110 during the manufacturing process of the display panel 110. When the gate driving circuit is of a gate-in-panel type, the gate driving circuit may be referred to as a gate-in-panel circuit (GIPC).

For example, the gate driving circuit may be disposed in the non-active area NDA of the display panel 110. As another example, the gate driving circuit may be disposed in the display area DA of the display panel 110. For example, the gate driving circuit may be disposed in a first partial area in the display area DA (e.g., a left area or a right area in the display area DA). As another example, the gate driving circuit may be disposed in a first partial area in the display area DA (e.g., a left area or right area in the display area DA) and a second partial area (e.g., a right area or left area in the display area DA). As another example, the gate driving circuit may be disposed over the entire display area DA.

When the gate driving circuit is disposed in the display area DA of the display panel 110, the gate driving circuit may vertically overlap the subpixels SP disposed in the display area DA. For example, the gate driving circuit may vertically overlap the light emitting elements and transistors included in the disposed subpixels SP in the display area DA. The gate driving circuit may vertically overlap a plurality of light emitting elements and a plurality of transistors included in a plurality of subpixels SP disposed in the display area DA. The gate driving circuit may include a plurality of transistors. Each of the plurality of transistors included in the gate driving circuit may include an active layer including a first semiconductor material, and each of the plurality of transistors included in the subpixels SP may include an active layer including a second semiconductor material. For example, the first semiconductor material and the second semiconductor material may be substantially identical. As another example, the first semiconductor material and the second semiconductor material may be different from each other. For example, the first semiconductor material may be a silicon-based semiconductor material, such as low temperature poly silicone (LTPS), and the second semiconductor material may be an oxide semiconductor material. For example, the active layer may be, but is not limited to, a semiconductor layer.

The controller is a device for controlling the data driving circuit and the gate driving circuit, and may control the driving timing for a plurality of data lines DL and the driving timing for a plurality of gate lines GL.

The controller may supply data driving control signals DCS to the data driving circuit to control the data driving circuit, and may supply gate driving control signals GCS to the gate driving circuit to control the gate driving circuit.

The controller may receive input image data from the host system and, based on the input image data, supply image data DATA to the data driving circuit.

The controller may be implemented as a separate component from the data driving circuit, or may be integrated with the data driving circuit into an integrated circuit.

The controller may be a timing controller used in display technology, or may be a control device that may include a timing controller to perform other control functions. Alternatively, the controller may be a control device different from the timing controller, or may be a circuit in the control device. The controller may be implemented as various circuits or electronic components such as an integrated circuit (IC), field programmable gate array (FPGA), application specific integrated circuit (ASIC), or processor, but is not limited thereto.

The controller may be mounted on a printed circuit board, a flexible printed circuit or the like, and may be electrically connected to a data driving circuit and a gate driving circuit through the printed circuit board, flexible printed circuit or the like.

The controller may transmit and receive signals with the data driving circuit according to one or more predetermined interfaces. The interface may include, e.g., a low voltage differential signaling (LVDS) interface, an embedded clock point-point interface (EPI), and a serial peripheral interface (SPI), but embodiments of the disclosure are not limited thereto.

The plurality of transistors may include a driving transistor DT for driving the light emitting element ED and a scan transistor ST that is turned on or off according to the scan signal SC.

The driving transistor DT may supply a driving current to the light emitting element ED. The scan transistor ST may be configured to control the electrical state of a corresponding node in the subpixel circuit SPC or to control the state or operation of the driving transistor DT. The at least one capacitor may include a storage capacitor Cst for maintaining a constant voltage during a frame.

To drive the subpixel SP, a data signal VDATA as an image signal and a scan signal SC which is a kind of gate signal may be applied to the subpixel SP. Further, for driving the subpixel SP, a common driving signal including the driving voltage VDD and the base voltage VSS may be applied to the subpixel SP.

The light emitting element ED may include a pixel electrode PE, an intermediate layer EL, and a common electrode CE. The intermediate layer EL may be disposed between the pixel electrode PE and the common electrode CE.

For example, the pixel electrode PE may be an electrode disposed in each subpixel SP, and the common electrode CE may be an electrode commonly disposed in all the subpixels SP. For example, the pixel electrode PE may be an anode, and the common electrode CE may be a cathode. As another example, the pixel electrode PE may be a cathode, and the common electrode CE may be an anode. For convenience of description, an example is described in which the pixel electrode PE is an anode, and the common electrode CE is a cathode.

If the light emitting element ED is an organic light emitting device, the intermediate layer EL may include a light emitting layer EML, a first common intermediate layer COM1 between the pixel electrode PE and the emission layer EML, and a second common intermediate layer COM2 between the emission layer EML and the common electrode CE. The first common intermediate layer COM1 and the second common intermediate layer COM2 may be collectively referred to as a common intermediate layer EL_COM.

The light emitting layer EML may be disposed for each subpixel SP or may be disposed commonly over a plurality of subpixels SP. The common intermediate layer EL_COM may be commonly disposed over the plurality of subpixels SP, but embodiments of the disclosure are not limited thereto.

In other words, the light emitting layer EML may be disposed for each emission area or disposed commonly across a plurality of emission areas. The common intermediate layer EL_COM may be commonly disposed across a plurality of emission areas and non-emission areas, but embodiments of the disclosure are not limited thereto.

For example, the first common intermediate layer COM1 may include a hole injection layer HIL, an electron blocking layer EBL, and a hole transfer layer HTL, but embodiments of the disclosure are not limited thereto. The second common intermediate layer COM2 may include an electron transport layer ETL, a hole blocking layer HBL, and an electron injection layer EIL, but embodiments of the disclosure are not limited thereto.

The hole injection layer HIL may inject holes from the pixel electrode PE into the hole transport layer HTL, and the hole transport layer HTL may transport holes to the light emitting layer EML. The electron injection layer EIL may inject electrons from the common electrode CE into the electron transport layer ETL, and the electron transport layer ETL may transport electrons to the light emitting layer EML.

For example, the common electrode CE may be electrically connected to the base voltage line VSSL. The base voltage VSS, which is one type of the common voltage, may be applied to the common electrode CE through the base voltage line VSSL. The pixel electrode PE may be electrically connected directly or indirectly (through another transistor) to the first node Na of the driving transistor DT of each subpixel SP. In the disclosure, “base voltage VSS” may also be referred to as a first common voltage, a low-potential power voltage, or a low-potential voltage, and “base voltage line VSSL” may also be referred to as a first common voltage line, a low-potential power voltage line, or a low-potential voltage line.

Each light emitting element ED may include portions where the pixel electrode PE, the light emitting layer EML in the intermediate layer LE, and the common electrode CE overlap. A predetermined light emitting area may be formed by each light emitting element ED. For example, the light emitting area of each light emitting element ED may include an overlapping area of the pixel electrode PE, the light emitting layer EML in the intermediate layer EL, and the common electrode CE.

For example, the light emitting element (ED) may be an organic light emitting diode (OLED), an inorganic material-based light emitting diode (LED), a quantum dot light emitting element, a micro LED, or a mini LED, but embodiments of the disclosure are not limited thereto. For example, when the light emitting element ED is an organic light emitting diode (OLED), the intermediate layer EL of the light emitting element ED may include an intermediate layer EL including an organic material.

The driving transistor DT may be a driving transistor for supplying a driving current to the light emitting element ED. The driving transistor DT may be connected between a driving voltage line VDDL and the light emitting element ED.

The driving transistor DT may include a first node Na, a second node Nb, and a third node Nc. The first node Na may be electrically connected to the light emitting element ED, the second node Nb may receive a data signal VDATA, and the third node Nc may receive a driving voltage VDD, which is another kind of common voltage, from the driving voltage line VDDL. The driving transistor DT may be connected on the first node Na and the third node Nc. In the disclosure, the driving voltage VDD may also be referred to as a second common voltage, high-potential power supply voltage, or high-potential voltage, and the driving voltage line VDDL may also be referred to as a second common voltage wiring, low-potential power supply voltage line, or low-potential voltage line.

In the driving transistor DT, the first node N1 may be a gate node, the second node N2 may be a source node or a drain node, and the third node N3 may be a drain node or a source node. Hereinafter, for convenience of description, an example is described in which in the driving transistor DT, the first node N1 may be a gate node, the second node N2 may be a source node, and the third node N3 may be a drain node, but embodiments of the disclosure are not limited thereto.

The scan transistor ST included in the subpixel circuit SPC illustrated in FIG. 2 may be a switching transistor for transferring the data signal VDATA, which is an image signal, to the first node N1, which is the gate node of the driving transistor DT.

The scan transistor ST may be controlled to be turned on and off by the scan signal SC, which is a kind of gate signal applied through the scan line SCL, which is a type of the gate line GL, to control electrical connection between the first node N1 of the driving transistor DT and the data line DL. The drain electrode or the source electrode of the scan transistor ST may be electrically connected to the data line DL, the source electrode or the drain electrode of the scan transistor ST may be electrically connected to the first node N1 of the driving transistor DT, and the gate electrode of the scan transistor ST may be electrically connected to the scan line SCL.

The storage capacitor Cst may be electrically connected between the second node N2 and second node Nb of the driving transistor DT. The storage capacitor Cst may include at least one capacitor electrode electrically connected to the second node N2 of the driving transistor DT or corresponding to the second node N2 of the driving transistor DT, and at least one capacitor electrode electrically connected to the first node N1 of the driving transistor DT or corresponding to the first node N1 of the driving transistor DT.

The capacitor Cst may be an external capacitor intentionally designed to be outside the driving transistor DT, but not a parasite capacitor (e.g., Cgs or Cgd) which is an internal capacitor that may be present between the second node N2 and the first node N1 of the driving transistor DT, but embodiments of the disclosure are not limited thereto.

Each of the driving transistor DT and the scan transistor ST may be an n-type transistor or a p-type transistor, but embodiments of the disclosure are not limited thereto. For example, one of the driving transistor DT and the scan transistor ST may be either an n-type transistor or a p-type transistor.

The display panel 110 may have a top emission structure or a bottom emission structure. When the display panel 110 has a top emission structure, at least a portion of the subpixel circuit SPC may overlap at least a portion of the light emitting element ED in a vertical direction. Accordingly, the area of the emission area may increase and the aperture ratio may increase. When the display panel 110 has a bottom emission structure, the subpixel circuit SPC may not overlap the light emitting element ED in the vertical direction.

The subpixel circuit SPC may have a 2T (transistor) 1C (capacitor) structure that includes two transistors DT and ST and one capacitor Cst, as shown in FIG. 2 and, in some cases, may further include one or more additional transistors or one or more additional capacitors.

For example, the subpixel circuit SPC may have a 3T1C structure including 3 transistors and 1 capacitor. For example, the subpixel circuit SPC may have a 8T1C structure including 8 transistors and 1 capacitor. As another example, the subpixel circuit SPC may have a 6T2C structure including 6 transistors and 2 capacitors. As another example, the subpixel circuit SPC may have a 7T1C structure including 7 transistors and 1 capacitor. Embodiments of the disclosure are not limited thereto.

Depending on the structure of the subpixel circuit SPC, the type and number of gate lines or the gate signals supplied to the subpixel SP may vary. Further, the type and number of common driving signals supplied to the subpixels SP may vary according to the structure of the subpixel circuit SPC.

Since the circuit elements (e.g., the light emitting element ED implemented as an organic light emitting diode (OLED) including an organic material) in each subpixel SP are vulnerable to external moisture or oxygen, the encapsulation layer 200 may be disposed on the display panel 110. The encapsulation layer 200 may prevent external moisture or oxygen from penetrating into circuit elements (e.g., the light emitting element ED). The encapsulation layer 200 may be configured in various forms to prevent the light emitting elements ED from contacting moisture or oxygen. For example, the encapsulation layer 200 may be constituted of two or more layers in which organic films and inorganic films are alternately stacked, but embodiments of the disclosure are not limited thereto.

Referring to FIG. 2, the display device 100 according to embodiments of the disclosure may have a touch screen panel TSP formed on the encapsulation layer 200 and embedded in the display panel 110 to provide a touch sensing function. In other words, in the display device 100, a plurality of touch electrodes TE forming the touch screen panel TSP may be disposed on the encapsulation layer 200 to constitute the display panel 110.

According to embodiments of the disclosure, the display device 100 may have not only the function of displaying images but also may further provide a touch sensing function that detects whether a touch has occurred by a touch object such as a finger or a pen, or detects the touch position.

For example, when the encapsulation layer 200 is composed of a plurality of layers, the touch electrode TE may be disposed between any first encapsulation layer and second encapsulation layer, but the disclosure is not limited thereto.

The display device 100 may sense a touch by a mutual capacitance method or a self-capacitance method as a capacitance-based touch sensing method.

In the mutual capacitance-based touch sensing method, the plurality of touch electrodes TE may be divided into a touch driving electrode to which the touch driving signal is applied through the touch driving line, and a touch sensing electrode where the touch sensing signal is sensed through the touch sensing line and which forms capacitance with the touch driving electrode. In this case, the touch driving line and the touch sensing line may be collectively referred to as a touch line, and the touch driving signal and the touch sensing signal may be collectively referred to as a touch signal.

In this case, the area of the touch driving electrode to which the touch driving signal is applied and the area of the touch sensing electrode to which the touch sensing signal is transmitted may be the same or different.

For example, the parasitic capacitance caused by the touch sensing electrode to which the touch sensing signal is transferred may be relatively reduced by forming the area of the touch sensing electrode to be smaller than the area of the touch driving electrode. In this case, the area of the touch driving electrode to which the touch driving signal is applied and the area of the touch sensing electrode to which the touch sensing signal is transferred may be in a ratio of 5:1 to 2:1. For example, the area of the touch driving electrode and the area of the touch sensing electrode may be in a ratio of 4:1, but the disclosure is not limited thereto.

In the case of such a mutual capacitance-based touch sensing scheme, the presence or absence of a touch and touch coordinates are detected based on a change in the mutual capacitance caused between the touch driving electrode and the touch sensing electrode according to the presence or absence of a pointer, such as a finger or a pen.

In the self-capacitance-based touch sensing scheme, each touch electrode TE plays a role both as a touch driving electrode and as a touch sensing electrode. In other words, the touch driving signal is applied to the touch electrode TE through one touch line, and the touch sensing signal transferred from the touch electrode TE to which the touch driving signal is applied is received through the same touch line. Accordingly, in the self-capacitance-based touch sensing scheme, there is no distinction between the touch driving electrode and the touch sensing electrode and no distinction between the touch driving line and the touch sensing line.

In the case of such a self-capacitance-based touch sensing scheme, the presence or absence of a touch and touch coordinates are detected based on a change in capacitance caused between a pointer, such as a finger or a pen, and the touch electrode TE.

Thus, the display device 100 may sense a touch using a mutual capacitance-based touch sensing method, or may sense a touch using a self-capacitance-based touch sensing method.

FIG. 3 is a view illustrating a bending structure and a wiring structure in a planar structure of the display panel 110 according to embodiments of the disclosure.

Referring to FIG. 3, a substrate 111 of a display panel 110 according to embodiments of the disclosure may include a display area DA and a non-display area NDA. The display area DA and the non-display area NDA may also be considered as areas of the display panel 110.

All of the lines and electrodes are formed on the substrate 111. In the display device 100 according to embodiments of the disclosure, the substrate 111 may be a flexible substrate capable of bending. In the disclosure, “bending” may have a meaning equivalent to “folding” or “flexible”.

The non-display area NDA is an area where an image is not displayed, and may be an area except for the display area DA. The subpixel SP is not disposed in the non-display area NDA. However, at least one dummy subpixel that is not directly involved in image display may be disposed in the non-display area NDA.

The non-display area NDA may include a first non-display area NDA1, a bending area BA, and a second non-display area NDA2.

The first non-display area NDA1 may be positioned around the display area DA, and may be an area closest to the display area DA among the first non-display area NDA1, the bending area BA, and the second non-display area NDA2.

The second non-display area NDA2 may include pad areas PA1 and PA2 where various pads are disposed, and may be an area farthest from the display area DA among the first non-display area NDA1, the bending area BA, and the second non-display area NDA2.

The bending area BA is an area where the substrate 111 is bent, and may be an area positioned between the first non-display area NDA1 and the second non-display area NDA2.

The substrate 111 may include a display area DA in which images are displayed and a non-display area NDA which is an area outside of the display area DA. A plurality of subpixels SP may be disposed in the display area DA. The non-display area NDA may include a gate in panel (GIP) area where a GIP-type gate driving circuit is formed, a bending area BA where various lines pass and a data driving circuit is electrically connected, and a second non-display area NDA2.

For example, the gate in panel (GIP) area may be positioned in the left outer area and/or the right outer area of the display area DA. The non-display area NDA may be positioned in an upper outer area (or a lower outer area) of the display area DA. The second non-display area NDA2 may be an outer area than the bending area BA, and may include pad areas PA1 and PA2 to which circuit components such as a printed circuit board are electrically connected.

As described above, the substrates (SUB) 111 may include a bending area BA that is bent and folded, and the bending area BA may be folded to be positioned on the lower surface of the unfolded portion. The bending area BA is a partial area of the non-display area NDA, and may be positioned in the driving circuit area to which the data driving circuit is electrically connected and between the driving circuit area and the display area DA.

In FIG. 2, according to the structure of the subpixel SP, for driving the subpixel SP, a plurality of driving voltage lines DVL for supplying the driving voltage VDD to the subpixel SP and one or more base voltage lines VSSL for applying the base voltage VSS to the common electrode CE of the light emitting element ED in each subpixel SP may be further disposed on the substrates (SUB) 111.

Referring to FIG. 3, for example, a plurality of driving voltage lines DVL may be arranged in the column direction, but are not limited thereto. In order to efficiently transfer the driving voltage VDD to the plurality of driving voltage lines DVL, a driving voltage pattern integrally or electrically connected to the plurality of driving voltage lines DVL may be disposed in the non-display area NDA.

The plurality of driving voltage lines DVL may electrically connect the bending area BA to the data driving circuit or the printed circuit board connected to the pad areas PA1 and PA2 through the driving voltage pattern. The pad areas PA1 and PA2 may be areas where various circuit components are connected. For example, the first pad area PA1 may be an area where driving circuits (e.g., the data driving circuit and/or the touch driving circuit) are bonded. The second pad area PA2 may be an area where the printed circuit board is connected. Various electronic components such as a timing controller and a touch controller may be mounted on the printed circuit board.

One or more base voltage lines VSSL may be disposed in the non-display area NDA to surround an outer area of the display area DA for efficient transfer of the base voltage VSS. Further, one or more base voltage lines VSSL may be electrically connected to the data driving circuit or the printed circuit board connected to the driving circuit area past the bending area BA.

A crack prevention pattern PCD may be formed on the substrates (SUB) 111. The crack prevention pattern PCD may be formed outside the base voltage line VSSL in the non-display area NDA, but the disclosure is not limited thereto.

For example, the crack prevention pattern PCD is a pattern for preventing cracks in lines passing through the substrate SUB 111, and may be formed in a zigzag pattern, but the disclosure is not limited thereto.

For example, when the bending area BA is bent, some of the signal lines passing through the bending area BA may be cracked (electrically opened) or short-circuited with neighboring signal lines. In this case, an accurate signal may not be transferred through a signal line that is cracked (opened) or short-circuited, and thus a problem with display driving or an image display may not be properly performed, and thus image quality may be greatly decreased. Thus, to prevent such issues, the crack prevention pattern PCD may be disposed, but the disclosure is not limited thereto.

The above-described display panel 110 uses a flexible substrate SUB, 111. By bending the bending area BA, which is a portion where the data driving circuit is connected, a portion of the substrate SUB, 111 may be folded backward. The folded bending area BA which is a portion which an image cannot be displayed is not visible from the front. Thus, by using the bending structure and wiring structure as illustrated in FIG. 3, it is possible to significantly reduce the bezel size of the display device 100—i.e., a narrow bezel design is possible which provides better aesthetic satisfaction.

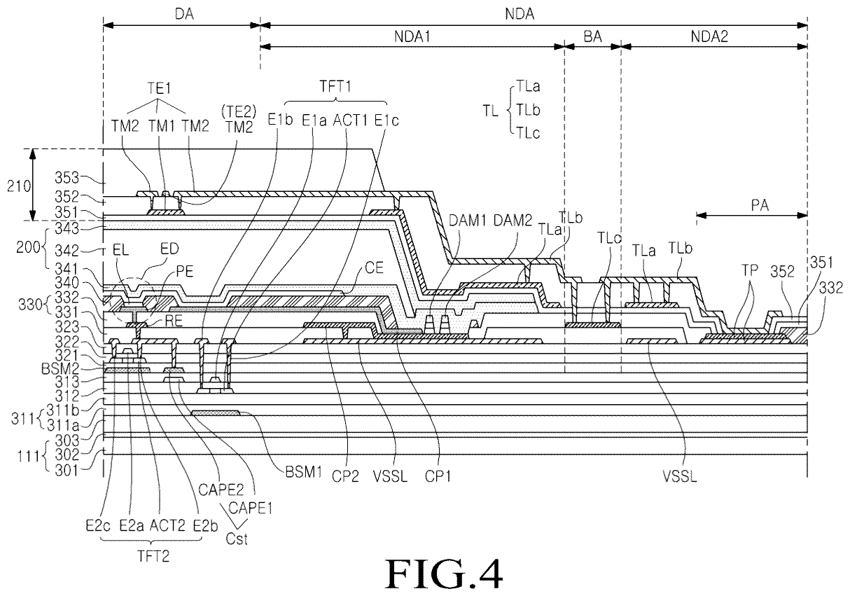

FIG. 4 is a view illustrating an example cross-sectional structure of the display panel 100 of FIG. 3 according to embodiments of the disclosure.

Referring to FIG. 4, the display panel 110 according to embodiments of the disclosure may include a substrate 111, a transistor unit, a light emitting element unit, and an encapsulation unit, but embodiments of the disclosure are not limited thereto.

The substrate 111 may be a single layer or multiple layers. When the substrate 111 includes multiple layers, the substrate 111 may include a first substrate 301, an intermediate substrate layer 302, and a second substrate 303. The intermediate substrate layer 302 may be positioned between the first substrate 301 and the second substrate 303. For example, each of the first substrate 301 and the second substrate 303 may be a polyimide (PI) layer, but embodiments of the disclosure are not limited thereto. The intermediate substrate layer 302 may be an inorganic insulation layer, but embodiments of the disclosure are not limited thereto. The intermediate substrate layer 302 may prevent electric charge accumulated on the first substrate 301, which is a polyimide layer, from affecting the transistors disposed on the second substrate 303 through the second substrate 303 which is a polyimide layer.

Further, the intermediate substrate layer 302 may prevent a moisture component from penetrating upward through the first substrate 301. For example, the intermediate substrate layer 302 may be formed of a single layer of silicon nitride (SiNx) or silicon oxide (SiOx) or multiple layers thereof, or may be formed of a double layer of silicon dioxide (SiO₂) and silicon nitride (SiNx), but is not limited thereto.

The transistor unit may include an insulation layer 311, 312, 313, 321, 322, and 323 on the substrate 111, thin film transistors TFT1 and TFT2, a storage capacitor Cst, and various electrodes or signal lines.

The thin film transistors TFT1 and TFT2 included in the transistor unit may include a first thin film transistor TFT1 and a second thin film transistor TFT2.

The first thin film transistor TFT1 may include a first active layer ACT1, a first electrode E1a, a second electrode E1b, and a third electrode E1c.

The first electrode E1a may be a gate electrode, the second electrode E1b may be a source electrode or a drain electrode, and the third electrode E1c may be a drain electrode or a source electrode. Hereinafter, for convenience of description, the first electrode E1a is referred to as a first gate electrode E1a, the second electrode E1b is referred to as a first source electrode E1b, and the third electrode E1c is referred to as a first drain electrode E1c, but embodiments of the disclosure are not limited thereto. However, embodiments of the disclosure are not limited thereto.

The first active layer ACT1 may include a first semiconductor material. For example, the first semiconductor material may include an oxide semiconductor, amorphous silicon, polysilicon, or low temperature polysilicon (LTPS), but embodiments of the disclosure are not limited thereto. The first thin film transistor TFT1 may be implemented as a p-channel transistor or an n-channel thin film transistor, but embodiments of the disclosure are not limited thereto.

The second thin film transistor TFT2 may include a second active layer ACT2, a fourth electrode E2a, a fifth electrode E2b, and a sixth electrode E2c.

The fourth electrode E2a may be a gate electrode, the fifth electrode E2b may be a source electrode or a drain electrode, and the sixth electrode E2c may be a drain electrode or a source electrode. Hereinafter, for convenience of description, the fourth electrode E2a is referred to as a second gate electrode E2a, the fifth electrode E2b is referred to as a second source electrode E2b, and the sixth electrode E2c is referred to as a second drain electrode E2c. However, embodiments of the disclosure are not limited thereto.

The second active layer ACT2 may include a second semiconductor material. For example, the second semiconductor material may include an oxide semiconductor, amorphous silicon, polysilicon, or low temperature polysilicon (LTPS), but embodiments of the disclosure are not limited thereto. The second thin film transistor TFT2 may be implemented as a p-channel transistor or an n-channel thin film transistor, but embodiments of the disclosure are not limited thereto.

The types of the respective semiconductor materials of the first active layer ACT1 of the first thin film transistor TFT1 and the second active layer ACT2 of the second thin film transistor TFT2 may be as follows.

For example, the first active layer ACT1 of the first thin film transistor TFT1 and the second active layer ACT2 of the second thin film transistor TFT2 may include an oxide semiconductor material. As another example, the first active layer ACT1 of the first thin film transistor TFT1 and the second active layer ACT2 of the second thin film transistor TFT2 may include a low-temperature polysilicon semiconductor material. As another example, the first active layer ACT1 of the first thin film transistor TFT1 may include a low-temperature polysilicon semiconductor material, and the second active layer ACT2 of the second thin film transistor TFT2 may include an oxide semiconductor material. As another example, the first active layer ACT1 of the first thin film transistor TFT1 may include an oxide semiconductor material, and the second active layer ACT2 of the second thin film transistor TFT2 may include a low-temperature polysilicon semiconductor material.

The purposes of the transistors in the display area DA may be as follows.

For example, all of the transistors in each subpixel SP may be implemented as first thin film transistors TFT1. As another example, all of the transistors in each subpixel SP may be implemented as second thin film transistors TFT2. As another example, some of all of the transistors in each subpixel SP may be implemented as first thin film transistors TFT1, and the others of the transistors may be implemented as second thin film transistors TFT2. In other words, each subpixel SP may include at least one first thin film transistor TFT1 and at least one second thin film transistor TFT2.

When some of all of the transistors in each subpixel SP are implemented as first thin film transistors TFT1 and the others are implemented as second thin film transistors TFT2, the following examples may be possible.

For example, in each subpixel SP, the driving transistor DT may be implemented as a first thin film transistor TFT1, and other transistors (e.g., the scan transistor ST, the emission control transistor, etc.) than the driving transistor DT may be implemented as second thin film transistors TFT2.

As another example, in each subpixel SP, the driving transistor DT may be implemented as a second thin film transistor TFT2, and other transistors (e.g., the scan transistor ST, the emission control transistor, etc.) than the driving transistor DT may be implemented as first thin film transistors TFT1.

In FIG. 4, the second thin film transistor TFT2 connected to the pixel electrode PE of the light emitting element ED may be a driving transistor DT or a transistor different from the driving transistor DT according to the configuration of the subpixel circuit SPC. For example, in FIG. 4, the second thin film transistor TFT2 connected to the pixel electrode PE of the light emitting element ED may be an emission control transistor connected between the driving transistor DT and the light emitting element ED.

The purposes of the transistors in the non-display area NDA may be as follows.

For example, the active layers of the transistors included in the gate-in-panel (GIP) type gate driving circuit may be formed of an oxide semiconductor material. As another example, the active layers of the transistors included in the gate-in-panel (GIP) type gate driving circuit may be formed of a low-temperature polysilicon semiconductor material. As another example, among the transistors included in the gate-in-panel (GIP) type gate driving circuit, some active layers may be formed of a low-temperature polysilicon semiconductor material, and other active layers may be formed of an oxide semiconductor material.

The second active layer ACT2 of the second thin film transistor TFT2 may be positioned higher from the substrate 111 than the first active layer ACT1 of the first thin film transistor TFT1.

The first buffer layer 311 may be disposed under the first active layer ACT1 of the first thin film transistor TFT1, and a second buffer layer 321 may be disposed under the second active layer ACT2 of the second thin film transistor TFT2. For example, the first active layer ACT1 of the first thin film transistor TFT1 may be positioned on the first buffer layer 311, and the second active layer ACT2 of the second thin film transistor TFT2 may be positioned on the second buffer layer 321. The second buffer layer 321 may be positioned higher than the first buffer layer 311.

The storage capacitor Cst may be disposed in various metal layers in the display panel 110. For example, the storage capacitor Cst may include a first capacitor electrode CAPE1 and a second capacitor CAPE2.

The light emitting element unit may include a plurality of light emitting elements ED disposed on the planarization layer 330. Each of the light emitting elements ED may include a pixel electrode PE, an intermediate layer EL, and a common electrode CE.

The encapsulation unit may include an encapsulation layer 200 on the plurality of light emitting elements ED. The encapsulation layer 200 may be a single layer or multiple layers, but embodiments of the disclosure are not limited thereto. In addition to the encapsulation layer 200, the encapsulation unit may further include at least one dam DAM for preventing a material constituting the encapsulation layer 200 from overflowing. In particular, when the second encapsulation layer 342 included in the encapsulation layer 200 is an organic encapsulation layer formed of an organic material, the dam DAM may prevent the organic material from overflowing.

Hereinafter, a structure or a vertical structure of the display panel 110 according to embodiments of the disclosure is described in more detail with reference to FIG. 4.

Referring to FIG. 4, the first buffer layer 311 may be disposed on the substrate 111. The first buffer layer 311 may be a single layer or multiple layers, but embodiments of the disclosure are not limited thereto. When the first buffer layer 311 includes multiple layers, the first buffer layer 311 may include a lower buffer layer 311a and an upper buffer layer 311b.

The first active layer ACT1 of the first thin film transistor TFT1 may be disposed on the first buffer layer 311. The first active layer ACT1 may include a channel area in which a channel is formed, a source connection area on one side of the channel area, and a drain connection area on the other side of the channel area.

The first gate insulation layer 312 may be disposed on the first active layer ACT1 of the first thin film transistor TFT1. The first gate electrode E1a of the first thin film transistor TFT1 may be disposed on the first gate insulation layer 312. The first inter-layer insulation layer 313 may be disposed on the first gate electrode E1a of the first thin film transistor TFT1. Here, the metal layer where the first gate electrode E1a of the first thin film transistor TFT1 is disposed may be referred to as a gate metal layer.

The second buffer layer 321 may be disposed on the first inter-layer insulation layer 313.

The second active layer ACT2 of the second thin film transistor TFT2 may be disposed on the second buffer layer 321. The second active layer ACT2 may include a channel area in which a channel is formed, a source connection area on one side of the channel area, and a drain connection area on the other side of the channel area.

The second gate insulation layer 322 may be disposed on the second active layer ACT2 of the second thin film transistor TFT2. The second gate electrode E2a of the second thin film transistor TFT2 may be disposed. The second inter-layer insulation layer 323 may be disposed on the second gate electrode E2a of the second thin film transistor TFT2. Here, the second gate electrode E2a of the second thin film transistor TFT2 may be referred to as a second gate metal layer.

The first source electrode E1b and the first drain electrode E1c of the first thin film transistor TFT1, and the second source electrode E2b and the second drain electrode E2c of the second thin film transistor TFT2 may be disposed on the second interlayer insulation layer 323.

The first source electrode E1b and the first drain electrode E1c of the first thin film transistor TFT1 may be connected to the source connection area and the drain connection area, respectively, of the first active layer ACT1 through holes of the second inter-layer insulation layer 323, the second gate insulation layer 322, the second buffer layer 321, the first inter-layer insulation layer 313, and the first gate insulation layer 312.

The second source electrode E2b and the second drain electrode E2c of the second thin film transistor TFT2 may be connected to the source connection area and the drain connection area, respectively, of the second active layer ACT2 through the holes of the second inter-layer insulation layer 323 and the second gate insulation layer 322.

The first source electrode E1b and the first drain electrode E1c of the first thin film transistor TFT1, and the second source electrode E2b and the second drain electrode E2c of the second thin film transistor TFT2 may include a first source-drain metal and may be disposed in the first source-drain metal layer.

Referring to FIG. 4, e.g., the storage capacitor Cst may be formed by a first capacitor electrode CAPE1 and a second capacitor electrode CAPE2. In some cases, the storage capacitor Cst may be formed by three or more capacitor electrodes, or may have a form in which two or more capacitors are connected in parallel.

Each of the first capacitor electrode CAPE1 and the second capacitor electrode CAPE2 may be disposed on various metal layers disposed in the display panel 110.

For example, the first capacitor electrode CAPE1 may include the same first gate metal as the first gate electrode E1a of the first thin film transistor TFT1 on the first gate insulation layer 312 and may be disposed in the first gate metal layer, but embodiments of the disclosure are not limited thereto. For example, the second capacitor electrode CAPE2 may be disposed on the first inter-layer insulation layer 313.

The second source electrode E2b of the second thin film transistor TFT2 may be electrically connected to the second capacitor electrode CAPE2 through holes of the second inter-layer insulation layer 323, the second gate insulation layer 322, and the second buffer layer 321.

For example, when the subpixel SP is configured as shown in FIG. 2, the first thin film transistor TFT1 may be the scanning transistor ST of FIG. 2, and the second thin film transistor TFT2 may be the driving transistor DT of FIG. 2.

Referring to FIG. 4, the transistor unit may further include a first shield pattern BSM1 disposed on the substrate 111. The first shield pattern BSM1 may overlap the first active layer ACT1 of the first thin film transistor TFT1. The first shield pattern BSM1 may be disposed under the first active layer ACT1 of the first thin film transistor TFT1. For example, the first shield pattern BSM1 may be disposed between the substrate 111 and the first buffer layer 311, or may be disposed between the lower buffer layer 311a and the upper buffer layer 311b.

The transistor unit may further include a second shield pattern BSM2 disposed on the substrate 111. The second shield pattern BSM2 may overlap the second active layer ACT2 of the second thin film transistor TFT2. The second shield pattern BSM2 may be disposed under the second active layer ACT2 of the second thin film transistor TFT2. For example, the second shield pattern BSM2 may be disposed in a metal layer between the first insulation layer 313 and the second buffer layer 321. The second shield pattern BSM2 may be disposed in the same metal layer as the second capacitor CAPE2, but embodiments of the disclosure are not limited thereto. As another example, the second shield pattern BSM2 may be disposed in the same first gate metal layer as the first gate electrode E1a of the first thin film transistor TFT1.

The planarization layer 330 may be disposed on the first thin film transistor TFT1 and the second thin film transistor TFT2, and may be disposed under the light emitting element ED. The planarization layer 330 may be an organic insulation layer including an organic insulating material.

For example, the planarization layer 330 may be constituted of one layer. As another example, the planarization layer 330 may include two layers. The planarization layer 330 may include a first planarization layer 331 and a second planarization layer 332. As another example, the planarization layer 330 may include three or more layers. Embodiments of the disclosure are not limited thereto.

Referring to FIG. 4, the first planarization layer 331 may be disposed on the first source electrode E1b and the first drain electrode E1c of the first thin film transistor TFT1, and the second source electrode E2b and the second drain electrode E2c of the second thin film transistor TFT2. For example, the first planarization layer 331 may be disposed on the first thin film transistor TFT1 and the second thin film transistor TFT2. For example, the first planarization layer 331 may be disposed while covering both the first thin film transistor TFT1 and the second thin film transistor TFT2.

Referring to FIG. 4, a connection electrode RE may be disposed on the first planarization layer 331. The connection electrode RE may electrically connect the second source electrode E2b of the second thin film transistor TFT2 and the pixel electrode PE.

The connection electrode RE may be electrically connected to the second source electrode E2b of the second thin film transistor TFT2 through the hole of the first planarization layer 331. The second source electrode E2b of the second thin film transistor TFT2 may be electrically connected to the second capacitor electrode CAPE2 of the storage capacitor Cst.

The connection electrode RE may be disposed in the second source-drain metal layer on the first planarization layer 331 and may include a second source-drain metal.

The second planarization layer 332 may be disposed on the connection electrode RE.

Referring to FIG. 4, the light emitting element unit may be disposed on the second planarization layer 332. The light emitting element ED may be formed on the second planarization layer 332. The light emitting element ED may include a pixel electrode PE, an intermediate layer EL, and a common electrode CE. The emission area of the light emitting element ED may be formed in an area in which the pixel electrode PE, the intermediate layer EL, and the common electrode CE overlap and contact each other.

The pixel electrode PE may be disposed on the second planarization layer 332. The pixel electrode PE may be electrically connected to the connection electrode RE through the hole of the second planarization layer 332.

A bank 340 may be disposed on the pixel electrode PE. The opening of the bank 340 may expose a portion of the pixel electrode PE to form the emission area. The opening of the bank 340 may overlap a portion of the pixel electrode PE.

For example, the bank 340 may be formed of a material including a black pigment, or an organic material such as a benzocyclobutene resin, a polyimide resin, an acrylic resin, or a photosensitive polymer, but embodiments of the disclosure are not limited thereto. When the bank 340 is formed of a material including a black pigment, a black dye, or the like, it may be a black bank. When the bank 340 is formed of a material including a black pigment or a black dye, light from the outside may be blocked or light reflected from the outside may be blocked, and thus the luminance of the display device 100 may be further enhanced.

The intermediate layer EL of the light emitting element ED may be disposed on a portion of the pixel electrode PE and the bank 340. The common electrode CE may be disposed on the intermediate layer EL.

Referring to FIG. 4, the encapsulation unit may be disposed on the light emitting element unit and may be positioned on the common electrode CE. The encapsulation unit may include the encapsulation layer 200 formed on the common electrode CE.

The encapsulation layer 200 may prevent moisture or oxygen from penetrating into the light emitting element ED. For example, the encapsulation layer 200 may prevent moisture or oxygen from penetrating into the organic material included in the intermediate layer EL of the light emitting element ED. The encapsulation layer 200 may be formed of a single layer or multiple layers, but embodiments of the disclosure are not limited thereto.

For example, the encapsulation layer 200 may include a first encapsulation layer 341, a second encapsulation layer 342, and a third encapsulation layer 343, but embodiments of the disclosure are not limited thereto. For example, the first encapsulation layer 341 and the third encapsulation layer 343 may include an inorganic layer, and the second encapsulation layer 342 may include an organic layer, but embodiments of the disclosure are not limited thereto.

The display panel 110 according to embodiments of the disclosure may have a built-in touch sensor. In this case, the display panel 110 according to embodiments of the disclosure may include a touch sensor layer 210 disposed on the encapsulation layer 200 and having a touch sensor.

Referring to FIG. 4, the touch sensor layer 210 may include a plurality of touch electrodes TE corresponding to touch sensors, and may include at least one touch metal layer for forming the plurality of touch electrodes TE.

For example, the touch sensor layer 210 may include a first touch metal layer on which a plurality of first touch metals TM1 are disposed, and a second touch metal layer on which a plurality of second touch metals TM2 are disposed, to form the plurality of touch electrodes TE. In this case, the touch sensor layer 210 may further include a touch interlayer insulation layer 352 disposed between the first touch metal layer and the second touch metal layer.

For example, one of the first touch metal layer and the second touch metal layer may be a sensor metal layer and the other may be a bridge metal layer.

For example, the first touch metal layer may be a bridge metal layer, and the second touch metal layer may be a sensor metal layer. In this case, the plurality of second touch metals TM2 disposed in the second touch metal layer may be sensor metals forming touch sensors, and the plurality of first touch metals TM1 disposed in the first touch metal layer may be bridge metals electrically connecting the plurality of second touch metals TM2, which are sensor metals. For example, two or more second touch metals TM2 and at least one first touch metal TM1 may constitute one first touch electrode TE1. In this case, two or more second touch metals TE2 may be electrically connected by at least one first touch metal TM1.

As another example, the first touch metal layer may be a sensor metal layer, and the second touch metal layer may be a bridge metal layer. In this case, the plurality of first touch metals TM1 disposed in the first touch metal layer may be sensor metals forming touch sensors, and the plurality of second touch metals TM2 disposed in the second touch metal layer may be bridge metals electrically connecting the plurality of first touch metals TM1, which are sensor metals.

As another example, each of the first touch metal layer and the second touch metal layer may be a sensor metal layer and a bridge metal layer. For example, the first touch metal layer may be a sensor metal layer and a bridge metal layer, and the second touch metal layer may be a sensor metal layer and a bridge metal layer. In this case, the plurality of first touch metals TM1 disposed in the first touch metal layer may include sensor metals and bridge metals, and the plurality of second touch metals TM2 disposed in the second touch metal layer may include sensor metals and bridge metals.

Referring to FIG. 4, the touch sensor layer 210 may further include a touch buffer layer 351 disposed on the encapsulation layer 200. The touch buffer layer 351 may be disposed between the encapsulation layer 200 and the touch metal layer. For example, the first touch metal layer may be disposed on the touch buffer layer 351, and the touch interlayer insulation layer 352 may be disposed on the first touch metal layer.

Referring to FIG. 4, the touch sensor layer 210 may further include a touch protection layer 353 disposed to cover the touch metal layer. For example, the touch protection layer 353 may be disposed on the second touch metal layer.

For example, the touch buffer layer 351 may be an inorganic layer including an inorganic insulating material or an organic layer including an organic insulating material, the touch interlayer insulation layer 352 may be an inorganic layer including an inorganic insulating material or an organic layer including an organic insulating material, and the touch protection layer 353 may be an inorganic layer including an inorganic insulating material or an organic layer including an organic insulating material.

For example, at least one of the touch buffer layer 351 and the touch interlayer insulation layer 352 may extend from the display area DA to the non-display area NDA. The touch protection layer 353 may be disposed to extend from the display area DA to the non-display area NDA.

The touch routing line TL may electrically connect the touch electrode TE and the touch pad TP. The touch routing line TL may be formed of at least one of the first touch metal TM1 and the second touch metal TM2.

For example, the touch routing line TL may be formed of the first touch metal TM1, or the touch routing line TL may be formed of the second touch metal TM2, or the first touch metal TM1 and the second touch metal TM2. When one touch routing line TL is formed of the first touch metal TM1 and the second touch metal TM2, the first touch metal TM1 and the second touch metal TM2 constituting one touch routing line TL may be electrically connected through a hole in the insulation layer 352.

For example, one touch routing line TL may include a plurality of wiring sections, and each of the plurality of wiring sections may be a single wiring section or a double wiring section. Here, the single wiring section may be a wiring section having one signal path, and the double wiring section may be a wiring section where two signal paths are connected in parallel.

The touch routing line TL may be disposed along the inclined surface of the encapsulation layer 200, and may extend to the touch pad TP through the upper portion of the dam DAM1 and DAM2.

The touch buffer layer 351 may have an opening exposing at least a portion of the touch pad TP. The touch routing line TL may be electrically connected to the touch pad TP through the opening of the touch buffer layer 351. The touch interlayer insulation layer 352 may be disposed on the touch routing line TL, and may extend to an area where the touch pad TP is disposed. The touch protection layer 353 may be disposed only in the display area DA, or may extend to the non-display area NDA to be disposed on the touch routing line TL. In some cases, the touch protection layer 353 may further extend to the upper portion of the touch pad TP.

Each of the plurality of touch electrodes TE may be a mesh-type electrode having a plurality of openings. In this case, each of the plurality of touch electrodes TE may be formed of at least one second touch metal TM2. However, embodiments of the disclosure are not limited thereto.

For example, the plurality of touch electrodes TE may include a first touch electrode TE1 and a second touch electrode TE2. When the first touch metal layer is a bridge metal layer and the second touch metal layer is a sensor metal layer, two or more second touch metals TM2 forming the first touch electrode TE1 corresponding to the touch sensor may be electrically connected through at least one first touch metal TM1, which are bridge metals. For example, the two second touch metals TM2 spaced apart from each other may be electrically connected by the first touch metal TM1 to constitute one first touch electrode TE1.

Referring to FIG. 4, the plurality of first touch metals TM1 and the plurality of second touch metals TM2 may be disposed not to overlap the light emitting element ED. The plurality of first touch metals TM1 and the plurality of second touch metals TM2 may overlap the bank 340. Accordingly, the luminous efficiency of the light emitting element ED may increase.

Referring to FIG. 4, the touch routing line TL may connect the touch pad TP disposed in the pad area PA in the second non-display area NDA2 and the first touch electrode TE1 disposed in the display area DA. To that end, the touch routing line TL may be disposed across the second non-display area NDA2, the bending area BA, and the first non-display area NDA1.

The touch routing line TL may include a first line section TLa, a second line section TLb, and a third line section TLc. For example, the touch routing line TL may include the first line section TLa and the second line section TLb disposed in the first non-display area NDA1 and the second non-display area NDA2, and the third line section TLc disposed in the bending area BA. The third line section TLc may connect the first line section TLa and the second line section TLb.

The first line section TLa of the touch routing line TL may extend along the inclined surface of the encapsulation layer 200 and may extend via the upper portion of at least one dam DAM1 or DAM2.

For example, the first line section TLa of the touch routing line TL may lead to the third line section TLc of the touch routing line TL through at least one of the first touch metal layer and the second touch metal layer.

The second line section TLb of the touch routing line TL may include at least one of a first touch metal layer where the first touch metal TM1 is disposed and a second touch metal layer where the second touch metal TM2 is disposed.

For example, the second line section TLb of the touch routing line TL may be formed of a second touch metal layer. As another example, the second line section TLb of the touch routing line TL may be configured by electrically connecting the first touch metal layer and the second touch metal layer.

For example, the second line section TLb of the touch routing line TL may be electrically connected to the touch pad TP through a contact hole (opening) that penetrates the second planarization layer 332, the touch buffer layer 351, and the touch interlayer insulation layer 352.

For example, the third line section TLc of the touch routing line TL may lead to the second line section TLb of the touch routing line TL.

The third line section TLc of the touch routing line TL may include a metal layer different from the first to third touch metal layers where the first to third touch metals TM1 and TM2 are disposed. For example, the metal layer included in the third line section TLc of the touch routing line TL may be the same as the metal layer where the electrode or line for display driving is disposed. For example, the metal layer included in the third line section TLc of the touch routing line TL may include a metal layer where the pixel electrode PE is disposed, but the disclosure is not limited thereto.

The touch pad TP is electrically connected to the second line section TLb of the touch routing line TL, and may include a metal layer different from the first to third touch metal layers. For example, the metal layer included in the touch pad TP may be the same as the metal layer where the electrode or line for display driving is disposed. For example, the metal layer included in the touch pad TP may include a metal layer where the pixel electrode PE is disposed, but the disclosure is not limited thereto.

Referring to FIG. 4, the display panel 100 according to embodiments of the disclosure may further include a common voltage line VSSL to which the common voltage VSS is applied and a connection pattern CP connecting the common electrode CE and the common voltage line VSSL. For example, the connection pattern CP may include the same material as that of the pixel electrode PE. For example, the connection pattern CP may include a first connection pattern CP1 and a second connection pattern CP2. For example, the first connection pattern CP1 may connect the common electrode CE and the second connection pattern CP2, and the second connection pattern CP2 may connect the first connection pattern CP1 and the common voltage line VSSL, but embodiments of the disclosure are not limited thereto.

As described above, delamination or cracks may occur at the end of the touch buffer layer due to the laser trimming line in the edge area of the bending area BA, where the printed circuit board is bent to the rear surface, and the first non-display area NDA1 around the bending area BA in the non-display area NDA of the display panel 110, causing moisture penetration and hence increasing defects, such as gate drain short (GDS) defects.

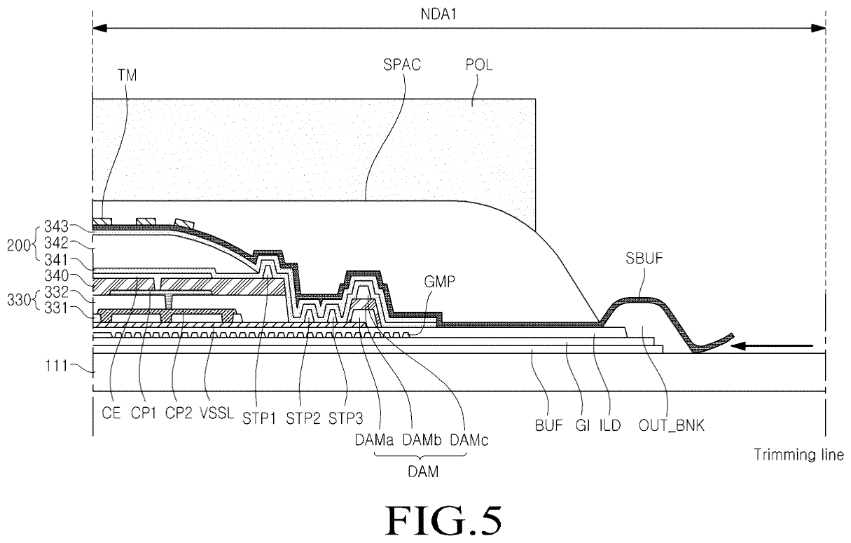

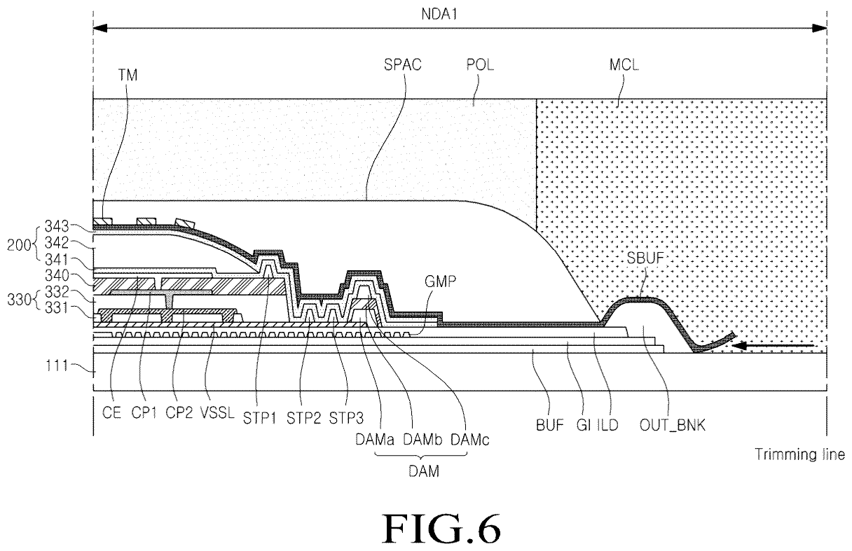

FIGS. 5 and 6 are views illustrating an example cross-sectional structure of a display panel 110 according to embodiments of the disclosure. Descriptions substantially the same as those described in FIG. 4 may be omitted.

Referring to FIG. 5 illustrating a cross-sectional structure of a first non-display area NDA1 of a display panel 110 according to embodiments of the disclosure, the display panel 110 may include a substrate 111, a transistor portion, a light emitting element unit, an encapsulation portion, and a touch sensor layer, but the embodiments of the disclosure are not limited thereto.

The substrate 111 may be formed of a single layer or a plurality of layers. For example, the substrate 111 may be a polyimide (PI) layer, but embodiments of the disclosure are not limited thereto.

The substrate 111 according to embodiments of the disclosure may include insulation layers BUF, GI, and ILD thereon. For example, the insulation layers may include a buffer layer BUF, a gate insulation layer GI disposed on the buffer layer BUF, and an inorganic insulation layer ILD disposed on the gate insulation layer GI, but the disclosure is not limited thereto. For example, the buffer layer BUF, the gate insulation layer GI, and the interlayer insulation layer ILD may have steps, but the disclosure is not limited thereto.

For example, it may further include an outer bank OUT_BNK disposed to cover the end portions of the insulation layers BUF, GI, and ILD having steps, but the disclosure is not limited thereto. For example, the outer bank OUT_BNK may be disposed on the insulation layers BUF, GI, and ILD, and one side thereof may contact the upper surface of the substrate 111, but is not limited thereto. For example, the outer bank OUT_BNK may be formed to prevent corrosion or defects caused by foreign objects (e.g., metal or dust) between the gaps between the steps of the insulation layers BUF, GI, and ILD, but the disclosure is not limited thereto.

For example, the outer bank OUT_BNK may include an organic material, but the disclosure is not limited thereto. For example, the outer bank OUT_BNK may be formed of a material including a black pigment, or an organic material such as a benzocyclobutene resin, a polyimide resin, an acrylic resin, or a photosensitive polymer, but embodiments of the disclosure are not limited thereto. When the outer bank OUT_BNK is formed of a material including a black pigment or a black dye, it may be a black bank.

The gate metal pattern GMP may be disposed on the gate insulation layer GI. The gate metal pattern GMP may be formed of the same material as the gate electrode material of the transistor. For example, the gate metal pattern GMP may be used as an electrode or signal line.

A planarization layer 330 may be disposed on the insulation layers BUF, GI, and ILD. For example, the planarization layer 330 may be an organic insulation layer including an organic insulating material.

For example, the planarization layer 330 may be constituted of one layer. As another example, the planarization layer 330 may include two layers. The planarization layer 330 may include a first planarization layer 331 and a second planarization layer 332. As another example, the planarization layer 330 may include three or more layers. Embodiments of the disclosure are not limited thereto.

The light emitting element unit may be disposed on the second planarization layer 332. The light emitting element ED may be formed on the second planarization layer 332. The light emitting element ED may include a pixel electrode PE, an intermediate layer EL, and a common electrode CE. The emission area of the light emitting element ED may be formed in an area in which the pixel electrode PE, the intermediate layer EL, and the common electrode CE overlap and contact each other. FIGS. 5 and 6 illustrate only the common electrode CE of the light emitting element unit to show only the connection structure.

A bank 340 may be disposed on the light emitting element unit. For example, the bank 340 may be disposed on the pixel electrode PE. The opening of the bank 340 may expose a portion of the pixel electrode PE to form the emission area. For example, the opening of the bank 340 may overlap a portion of the pixel electrode PE. For example, the intermediate layer EL of the light emitting element ED may be disposed on a portion of the pixel electrode PE and the bank 340. The common electrode CE may be disposed on the intermediate layer EL, but the disclosure is not limited thereto.

For example, the bank 340 may be formed of a material including a black pigment, or an organic material such as a benzocyclobutene resin, a polyimide resin, an acrylic resin, or a photosensitive polymer, but embodiments of the disclosure are not limited thereto. When the bank 340 is formed of a material including a black pigment, a black dye, or the like, it may be a black bank. When the bank 340 is formed of a material including a black pigment or a black dye, light from the outside may be blocked or light reflected from the outside may be blocked, and thus the luminance of the display device 100 may be further enhanced.

Referring to FIGS. 5 and 6, the encapsulation unit may be disposed on the light emitting element unit and may be positioned on the common electrode CE. The encapsulation unit may include the encapsulation layer 200 formed on the common electrode CE.

For example, the encapsulation layer 200 may prevent moisture or oxygen from penetrating into the light emitting element ED. For example, the encapsulation layer 200 may prevent moisture or oxygen from penetrating into the organic material included in the intermediate layer EL of the light emitting element ED. The encapsulation layer 200 may be formed of a single layer or multiple layers, but embodiments of the disclosure are not limited thereto.

For example, the encapsulation layer 200 may include a first inorganic layer 341, a first organic layer 342, and a second inorganic layer 343, but embodiments of the disclosure are not limited thereto. As another example, the first inorganic layer 341 and the second inorganic layer 343 may include an inorganic encapsulation layer, and the first organic layer 342 may include an organic encapsulation layer, but embodiments of the disclosure are not limited thereto.

For example, the first inorganic layer 341 may be disposed on the common electrode CE of the light emitting element. For example, the first organic layer 342 is disposed on the first inorganic layer 341 and may include an inclined surface. For example, the second inorganic layer 343 may be disposed on the first organic layer 342. For example, at least one of the first inorganic layer 341 and the second inorganic layer 343 may extend further outward than the first organic layer 342, but the disclosure is not limited thereto.

The display panel 110 according to embodiments of the disclosure may further include a dam DAM. For example, the dam DAM may further include at least one dam DAM positioned outside the first organic layer 342. For example, at least one of the first inorganic layer 341 and the second inorganic layer 343 may extend over the upper portion of the at least one dam to the outer periphery of the at least one dam DAM, but the disclosure is not limited thereto.

The display panel 110 according to embodiments of the disclosure may further include a first stopper STP1. For example, the first stopper STP1 is disposed on the outer portion of the bank 340 and may be positioned further outward than the first organic layer 342, but the disclosure is not limited thereto. For example, at least one of the first inorganic layer 341 and the second inorganic layer 343 may extend along the side surfaces of the insulation layers BUF, GI, and ILD past the upper and side surfaces of the first stopper STP1, but the disclosure is not limited thereto. For example, the first stopper STP1 may include an organic material, but the disclosure is not limited thereto. For example, the first stopper STP1 may be formed of the same material as the bank 340 and the outer bank OUT_BNK, but the disclosure is not limited thereto.

The display panel 110 according to embodiments of the disclosure may further include a second stopper STP2 disposed on the interlayer insulation layer ILD. For example, the second stopper STP2 may be positioned between the first stopper STP1 and at least one dam DAM, but the disclosure is not limited thereto. For example, the second stopper STP2 may include an organic material, but the disclosure is not limited thereto. For example, the second stopper STP2 may be formed of the same material as the bank 340 and the outer bank OUT_BNK, but the disclosure is not limited thereto.

The display panel 110 according to embodiments of the disclosure may further include a third stopper STP3 disposed on the interlayer insulation layer ILD. For example, the third stopper STP3 may be positioned between one of the first stopper STP1 and the second stopper STP2 and at least one dam DAM, but the disclosure is not limited thereto. For example, the third stopper STP3 may include an organic material, but the disclosure is not limited thereto. For example, the third stopper STP3 may be formed of the same material as the bank 340 and the outer bank OUT_BNK, but the disclosure is not limited thereto.

For example, the dam DAM may include a first dam DAMa, a second dam DAMb, and a third dam DAMc, but the disclosure is not limited thereto. For example, the first dam DAMa may be formed of the same material as the second planarization layer 332, but the disclosure is not limited thereto. For example, the second dam DAMb may be formed of the same material as the bank 340 and the outer bank OUT_BNK, but the disclosure is not limited thereto. For example, the third dam DAMc may be formed of the same material as the first stopper STP1, but the disclosure is not limited thereto.

Referring to FIGS. 5 and 6, the display panel 110 of the display device 100 according to embodiments of the disclosure may further include a common voltage line VSSL to which the common voltage VSS is applied, and a connection pattern CP connecting the common electrode CE and the common voltage line VSSL. The common voltage line VSSL may be disposed on the interlayer insulation layer ILD of the insulation layers BUF, GI, and ILD, and may overlap at least a portion of the rear surface of the at least one dam STP1, STP2, STP3, and DAM.

For example, the common voltage line VSSL may include the same material as the source electrode or the drain electrode of the transistor disposed in the display area DA, but the disclosure is not limited thereto.

For example, the connection pattern CP may include a first connection pattern CP1 and a second connection pattern CP2. For example, the first connection pattern CP1 may be disposed on the second planarization layer 332 to connect the common electrode CE and the second connection pattern CP2. For example, the first connection pattern CP1 may include the same material as that of the pixel electrode PE, but the disclosure is not limited thereto.

For example, the second connection pattern CP2 may be disposed on the first planarization layer 331 to connect the first connection pattern CP1 to the common voltage line VSSL disposed on the interlayer insulation layer ILD, but the disclosure is not limited thereto. For example, the second connection pattern CP2 may include the same material as the source electrode E2c of the transistor TFT2 connected to the light emitting element ED of the display area DA or the connection electrode RE electrically connecting the drain electrode E2c to the first electrode PE of the light emitting element ED, but the disclosure is not limited thereto.

Referring to FIGS. 5 and 6, a touch sensor layer may be further included on the encapsulation layer 200. For example, the touch sensor layer may include a touch buffer layer SBUF, a touch metal TM, and a touch protective layer SPAC, but the disclosure is not limited thereto.

The touch buffer layer SBUF may be disposed on the encapsulation layer 200. For example, the touch buffer layer SBUF may extend from the display area DA to the non-display area NDA and extend to the outer area of the encapsulation layer 200. For example, the touch buffer layer SBUF may cover at least one end of the first inorganic layer 341 and the second inorganic layer 343. For example, the touch buffer layer SBUF may be disposed to cover the outer surface of the outer bank OUT_BNK, and may contact the upper surface of the substrate 111 outside the outer bank OUT_BNK, but the disclosure is not limited thereto.

Referring to FIGS. 5 and 6, the touch metal TM may be disposed on the touch buffer layer SBUF. For example, a plurality of touch metals TM may be formed. For example, the touch metal TM may include a touch metal layer including the touch metal TM to form a touch electrode.

For example, the touch metal TM may include a first touch metal TM1 and a second touch metal TM2, and may include a first touch metal layer where a plurality of first touch metals TM1 are disposed, and a second touch metal layer where a plurality of second touch metals TM2 are disposed. For example, the touch sensor layer may further include a touch interlayer insulation layer disposed between the first touch metal layer and the second touch metal layer, but the disclosure is not limited thereto.

For example, the touch buffer layer SBUF may be disposed between the encapsulation layer 200 and the touch metal layer. For example, a first touch metal layer may be disposed on the touch buffer layer SBUF, and a touch interlayer insulation layer may be disposed on the first touch metal layer, but the disclosure is not limited thereto.

Referring to FIGS. 5 and 6, the touch sensor layer may further include a touch protective layer SPAC disposed to cover the touch metal TM. For example, the touch protective layer SPAC may be disposed on the second touch metal layer. For example, the touch protective layer SPAC may extend from the display area DA to the non-display area NDA, but the disclosure is not limited thereto.

For example, the touch buffer layer SBUF may be an inorganic layer including an inorganic insulating material or an organic layer including an organic insulating material, the touch interlayer insulation layer may be an inorganic layer including an inorganic insulating material or an organic layer including an organic insulating material, and the touch protective layer SPAC may be an inorganic layer including an inorganic insulating material or an organic layer including an organic insulating material, but the disclosure is not limited thereto.

Referring to FIGS. 5 and 6, the display panel 110 according to embodiments of the disclosure may further include a polarization layer POL. For example, the polarization layer POL extends from the display area DA to the non-display area NDA and may be disposed on the touch protective layer SPAC, but the disclosure is not limited thereto. For example, the outer bank OUT_BNK may be positioned further outward than the polarization layer POL, but the disclosure is not limited thereto.

Referring to FIG. 5, the display panel 110 having such a structure according to embodiments of the disclosure may exhibit low adhesion between the touch buffer layer SBUF and the substrate 111. As a result, delamination or cracks may occur at the end of the touch buffer layer SBUF, allowing moisture to penetrate the affected area, potentially causing a gate drain short (GDS) defect.

The display panel 110 of the display device 100 according to embodiments of the disclosure discloses a structure for preventing moisture from penetrating into the touch buffer layer SBUF.

Referring to FIG. 6 illustrating a cross-sectional structure of the first non-display area NDA1 of the display panel 110 according to embodiments of the disclosure, a micro-coating layer MCL may further be included in the structure of the display panel 110 of FIG. 5.

Referring to FIG. 6, the micro-coating layer MCL may be positioned outside the polarization layer POL in the first non-display area NDA1 and may overlap an outer portion of the touch protective layer SPAC. For example, the micro-coating layer MCL may prevent foreign objects or moisture introduced from the outside or prevent bending cracks or damage in the bending area BA formed around the first non-display area NDA1, but the disclosure is not limited thereto.

For example, the micro-coating layer MCL may be formed of a viscous polymer material. For example, the micro-coating layer MCL may prevent moisture penetration while protecting the signal line from external impact. For example, when the bending area BA is bent in a curved shape with a constant radius of curvature, a signal line may be positioned on the neutral plane of the micro-coating layer MCL where tensile and compressive forces become zero, but the disclosure is not limited thereto.

Therefore, the micro-coating layer MCL may reduce signal lines from being damaged by stress generated during bending and may be composed of organic materials, so it has excellent adhesion to the substrate 111, reducing cracking or delamination at the end of the touch buffer layer SUF.

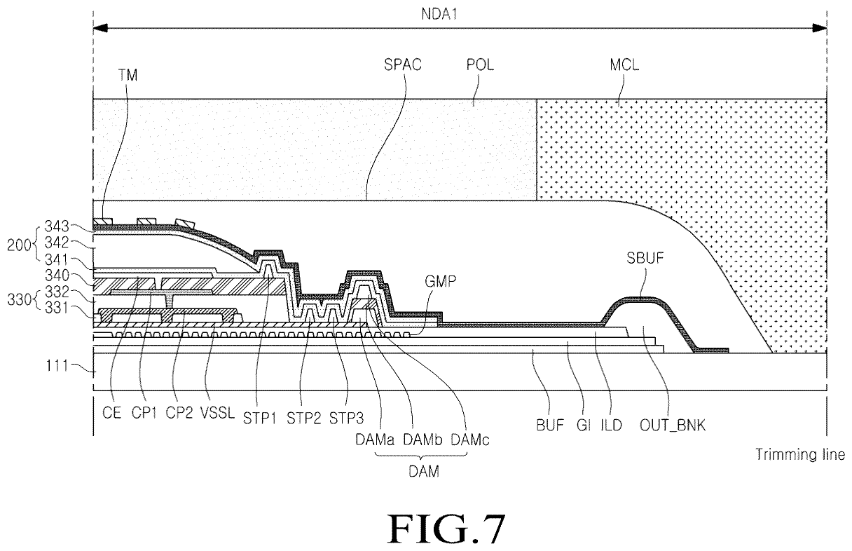

FIG. 7 is a view illustrating a cross-sectional structure of a display panel according to embodiments of the disclosure.

Referring to FIG. 7, the first non-display area NDA1 of the display panel 110 according to embodiments of the disclosure may include a substrate 111, insulation layers BUF, GI and ILD, a planarization layer 330, an encapsulation layer 200, and a touch sensor layer, but embodiments of the disclosure are not limited thereto.

Referring to FIG. 7, the first non-display area NDA1 may further include a touch sensor layer on the encapsulation layer 200. For example, the touch sensor layer may include a touch buffer layer SBUF, a touch metal TM, and a touch protective layer SPAC, but the disclosure is not limited thereto.

The touch buffer layer SBUF may be disposed on the encapsulation layer 200. For example, the touch buffer layer SBUF may extend from the display area DA to the non-display area NDA and extend to the outer area of the encapsulation layer 200. For example, the touch buffer layer SBUF may cover at least one end of the first inorganic layer 341 and the second inorganic layer 343. For example, the touch buffer layer SBUF may be disposed to cover the outer surface of the outer bank OUT_BNK, and may contact the upper surface of the substrate 111 outside the outer bank OUT_BNK, but the disclosure is not limited thereto.

The touch sensor layer may further include a touch metal TM disposed on the touch buffer layer SBUF. For example, a plurality of touch metals TM may be formed. For example, the touch metal TM may include a touch metal layer including the touch metal TM to form a touch electrode.

For example, the touch metal TM may include a first touch metal TM1 and a second touch metal TM2, and may include a first touch metal layer where a plurality of first touch metals TM1 are disposed, and a second touch metal layer where a plurality of second touch metals TM2 are disposed. For example, the touch sensor layer may further include a touch interlayer insulation layer disposed between the first touch metal layer and the second touch metal layer, but the disclosure is not limited thereto.

For example, the touch buffer layer SBUF may be disposed between the encapsulation layer 200 and the touch metal layer. For example, a first touch metal layer may be disposed on the touch buffer layer SBUF, and a touch interlayer insulation layer may be disposed on the first touch metal layer, but the disclosure is not limited thereto.

The touch sensor layer may further include a touch protective layer SPAC disposed to cover the touch metal TM. For example, the touch protective layer SPAC may be disposed on the second touch metal layer. For example, the touch protective layer SPAC may extend from the display area DA to the first non-display area NDA1 of the non-display area NDA, but the disclosure is not limited thereto.

For example, the touch protective layer SPAC may cover the edge of the touch buffer layer SBUF and may contact the upper surface of the substrate 111 outside the edge of the touch buffer layer SBUF, but the disclosure is not limited thereto. For example, the touch protection layer SPAC may be extended to cover the edge of the touch buffer layer SBUF, thereby reducing cracking or delamination at the end of the touch buffer layer SBUF, but the disclosure is not limited thereto.

For example, the touch buffer layer SBUF may be an inorganic layer including an inorganic insulating material or an organic layer including an organic insulating material, the touch interlayer insulation layer may be an inorganic layer including an inorganic insulating material or an organic layer including an organic insulating material, and the touch protective layer SPAC may be an inorganic layer including an inorganic insulating material or an organic layer including an organic insulating material, but the disclosure is not limited thereto.

The display panel 110 according to embodiments of the disclosure may further include a polarization layer POL. For example, the polarization layer POL extends from the display area DA to the first non-display area NDA1 of the non-display area NDA and may be disposed on the touch protective layer SPAC, but the disclosure is not limited thereto. For example, the outer bank OUT_BNK may be positioned further outward than the polarization layer POL, but the disclosure is not limited thereto. For example, the polarization layer POL may be formed to overlap the trench TRC, but the disclosure is not limited thereto.

The display panel 110 according to embodiments of the disclosure may further include a micro-coating layer MCL. For example, the micro-coating layer MCL may be positioned outside the polarization layer POL in the first non-display area NDA1 and may overlap an outer portion of the touch protective layer SPAC.

For example, the micro-coating layer MCL may prevent foreign objects or moisture introduced from the outside or prevent bending cracks or damage in the bending area BA formed around the first non-display area NDA1, but the disclosure is not limited thereto.

For example, the micro-coating layer MCL may be formed of a viscous polymer material. For example, the micro-coating layer MCL may prevent moisture penetration while protecting the signal line from external impact. For example, when the bending area BA is bent in a curved shape with a constant radius of curvature, a signal line may be positioned on the neutral plane of the micro-coating layer MCL where tensile and compressive forces become zero, but the disclosure is not limited thereto.

The display panel 110 according to embodiments of the disclosure may further include a dam DAM. For example, the dam DAM may further include at least one dam DAM positioned outside the first organic layer 342. For example, at least one of the first inorganic layer 341 and the second inorganic layer 343 may extend over the upper portion of the at least one dam to the outer periphery of the at least one dam DAM, but the disclosure is not limited thereto.

The display panel 110 according to embodiments of the disclosure may further include a first stopper STP1. For example, the first stopper STP1 is disposed on the outer portion of the bank 340 and may be positioned further outward than the first organic layer 342, but the disclosure is not limited thereto. For example, at least one of the first inorganic layer 341 and the second inorganic layer 343 may extend along the side surfaces of the insulation layers BUF, GI, and ILD past the upper and side surfaces of the first stopper STP1, but the disclosure is not limited thereto. For example, the first stopper STP1 may include an organic material, but the disclosure is not limited thereto. For example, the first stopper STP1 may be formed of the same material as the bank 340 and the outer bank OUT_BNK, but the disclosure is not limited thereto.

The display panel 110 according to embodiments of the disclosure may further include a second stopper STP2 disposed on the interlayer insulation layer ILD. For example, the second stopper STP2 may be positioned between the first stopper STP1 and at least one dam DAM, but the disclosure is not limited thereto. For example, the second stopper STP2 may include an organic material, but the disclosure is not limited thereto. For example, the second stopper STP2 may be formed of the same material as the bank 340 and the outer bank OUT_BNK, but the disclosure is not limited thereto.

The display panel 110 according to embodiments of the disclosure may further include a third stopper STP3 disposed on the interlayer insulation layer ILD. For example, the third stopper STP3 may be positioned between one of the first stopper STP1 and the second stopper STP2 and at least one dam DAM, but the disclosure is not limited thereto. For example, the third stopper STP3 may include an organic material, but the disclosure is not limited thereto. For example, the third stopper STP3 may be formed of the same material as the bank 340 and the outer bank OUT_BNK, but the disclosure is not limited thereto.

For example, the dam DAM may include a first dam DAMa, a second dam DAMb, and a third dam DAMc, but the disclosure is not limited thereto. For example, the first dam DAMa may be formed of the same material as the second planarization layer 332, but the disclosure is not limited thereto. For example, the second dam DAMb may be formed of the same material as the bank 340 and the outer bank OUT_BNK, but the disclosure is not limited thereto. For example, the third dam DAMc may be formed of the same material as the first stopper STP1, but the disclosure is not limited thereto.

Referring to FIG. 7, the display panel 110 according to embodiments of the disclosure having such a structure may reduce delamination or cracking at the end of the touch buffer layer SBUF by allowing the highly adhesive touch protection layer SPAC of the substrate 111 to extend to cover the edge of the touch buffer layer SBUF. However, cracking or delamination at the end of the touch buffer layer SBUF may still occur, resulting in ingress of moisture through the gaps between the insulation layer BUF, GI, and ILD to the display area DA, causing a gate drain short (GDS).

According to embodiments of the disclosure, the display panel 110 of the display device 100 has a structure capable of reducing the influence on the touch buffer layer SBUF despite delamination or cracking at the end of the micro-coating layer MCL when a laser trimming line is formed in an edge area of the first non-display area NDA1.

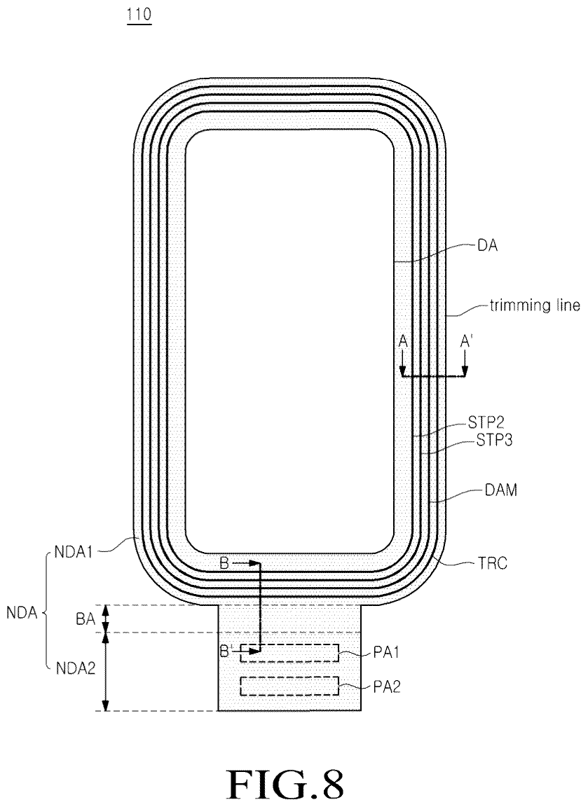

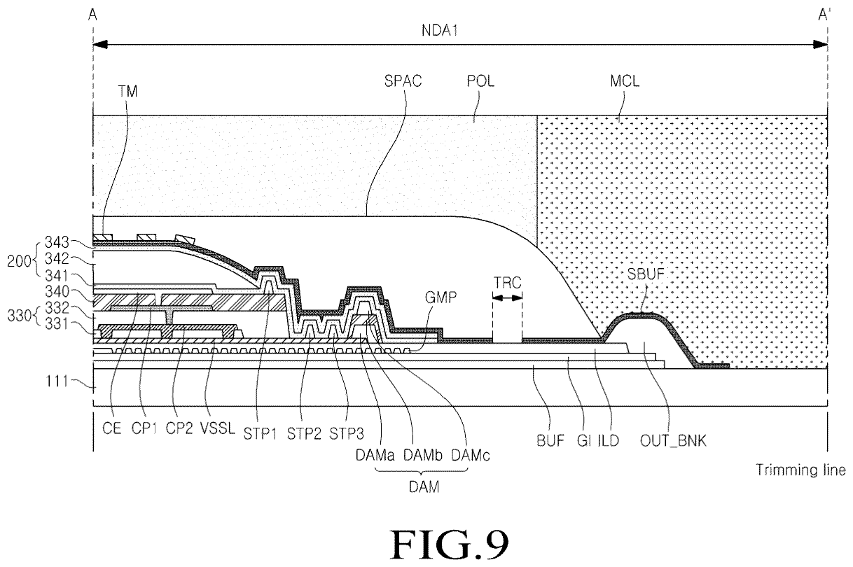

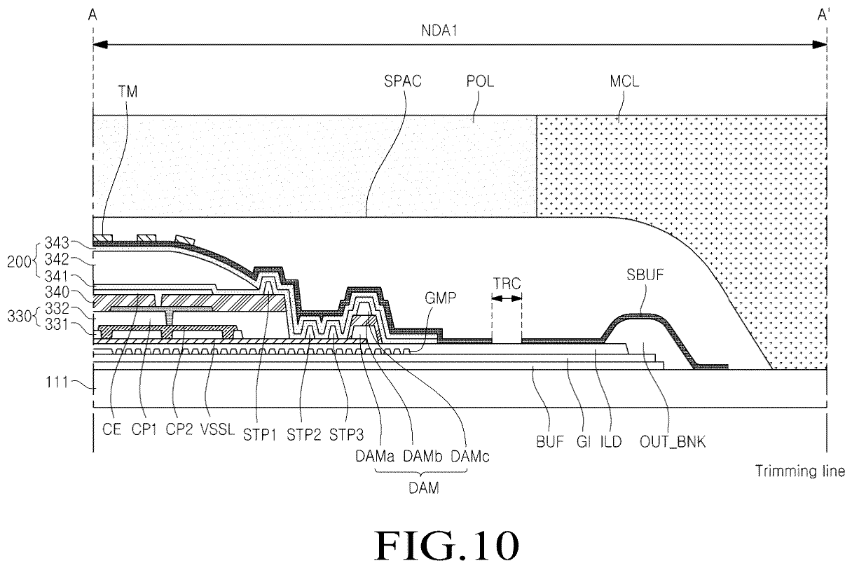

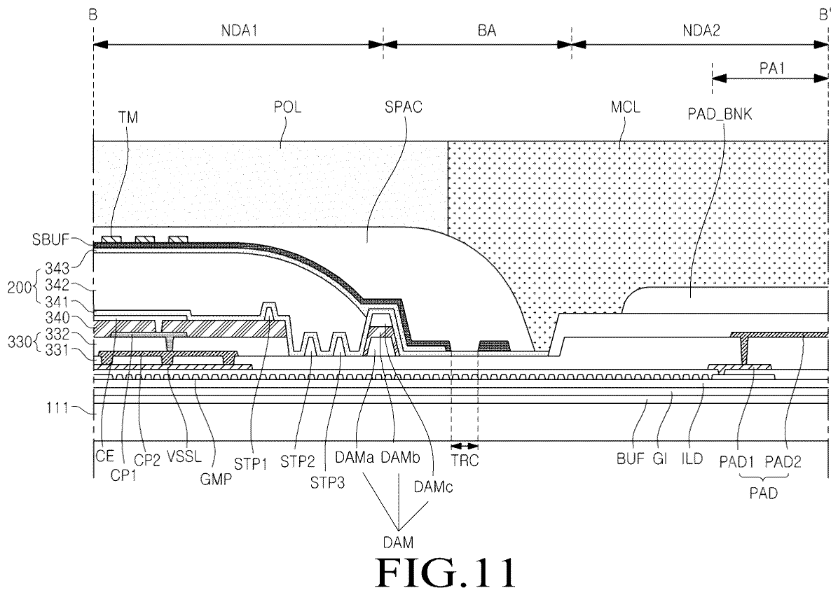

FIG. 8 is a view illustrating an example of a planar structure of a display panel according to embodiments of the disclosure, FIGS. 9 to 10 are cross-sectional views taken along line A-A′ of FIG. 8 according to embodiments of the disclosure, and FIG. 11 is a cross-sectional view taken along line B-B′ of FIG. 8 according to embodiments of the disclosure.

Referring to FIG. 8, the display panel 110 according to embodiments of the disclosure may include a display area DA and a non-display area NDA. The non-display area NDA is an area where an image is not displayed, and may be an area except for the display area DA. The subpixel SP is not disposed in the non-display area NDA. However, at least one dummy subpixel that is not directly involved in image display may be disposed in the non-display area NDA. Descriptions substantially the same as those described in FIG. 3 may be omitted.

The non-display area NDA may include a first non-display area NDA1, a bending area BA, and a second non-display area NDA2.

The substrate may include a display area DA in which images are displayed and a non-display area NDA which is an area outside of the display area DA. A plurality of subpixels SP may be disposed in the display area DA. The non-display area NDA may include a gate in panel (GIP) area where a GIP-type gate driving circuit is formed, a bending area BA where various lines pass and a data driving circuit is electrically connected, and a second non-display area NDA2.

The first non-display area NDA1 may be positioned around the display area DA, and may be an area closest to the display area DA among the first non-display area NDA1, the bending area BA, and the second non-display area NDA2.

The second non-display area NDA2 may include pad areas PA1 and PA2 where various pads are disposed, and may be an area farthest from the display area DA among the first non-display area NDA1, the bending area BA, and the second non-display area NDA2.

The bending area BA is an area where the substrate is bent, and may be an area positioned between the first non-display area NDA1 and the second non-display area NDA2.

For example, the outer area of the first non-display area NDA1 may include, but is not limited to, a second stopper STP2, a third stopper STP3, a dam DAM, and a trench TRC. The structures of the first non-display area NDA1, the bending area BA, and the second non-display area NDA2 included in the non-display area NDA of the display panel 110 according to embodiments of the disclosure are described in detail in FIGS. 9 to 12 below. Descriptions substantially the same as those described in FIGS. 4 to 7 may be omitted.

Referring to FIG. 9, the first non-display area NDA1 of the display panel 110 according to embodiments of the disclosure may include a substrate 111, insulation layers BUF, GI and ILD, a planarization layer 330, an encapsulation layer 200, and a touch sensor layer, but embodiments of the disclosure are not limited thereto.

Referring to FIG. 9, the first non-display area NDA1 may further include a touch sensor layer on the encapsulation layer 200. For example, the touch sensor layer may include a touch buffer layer SBUF, a touch metal TM, and a touch protective layer SPAC, but the disclosure is not limited thereto.

The touch buffer layer SBUF may be disposed on the encapsulation layer 200. For example, the touch buffer layer SBUF may extend from the display area DA to the non-display area NDA and extend to the outer area of the encapsulation layer 200. For example, the touch buffer layer SBUF may cover at least one end of the first inorganic layer 341 and the second inorganic layer 343. For example, the touch buffer layer SBUF may be disposed to cover the outer surface of the outer bank OUT_BNK, and may contact the upper surface of the substrate 111 outside the outer bank OUT_BNK, but the disclosure is not limited thereto.

For example, the touch buffer layer SBUF may extend from the display area DA to the first non-display area NDA1 of the non-display area NDA, and may extend to the outer area of the encapsulation layer 200 and may include the trench TRC positioned in the outer area of the encapsulation layer 200, but the disclosure is not limited thereto. For example, by including a trench TRC in the touch buffer layer SBUF, when the touch buffer layer SBUF is delaminated or cracked, moisture may be prevented from flowing into it, thereby reducing gate drain short (GDS) occurrences due to moisture, but the disclosure is not limited thereto.

The touch sensor layer may further include a touch metal TM disposed on the touch buffer layer SBUF. For example, a plurality of touch metals TM may be formed. For example, the touch metal TM may include a touch metal layer including the touch metal TM to form a touch electrode.

For example, the touch metal TM may include a first touch metal TM1 and a second touch metal TM2, and may include a first touch metal layer where a plurality of first touch metals TM1 are disposed, and a second touch metal layer where a plurality of second touch metals TM2 are disposed. For example, the touch sensor layer may further include a touch interlayer insulation layer disposed between the first touch metal layer and the second touch metal layer, but the disclosure is not limited thereto.

For example, the touch buffer layer SBUF may be disposed between the encapsulation layer 200 and the touch metal layer. For example, a first touch metal layer may be disposed on the touch buffer layer SBUF, and a touch interlayer insulation layer may be disposed on the first touch metal layer, but the disclosure is not limited thereto.

The touch sensor layer may further include a touch protective layer SPAC disposed to cover the touch metal TM. For example, the touch protective layer SPAC may be disposed on the second touch metal layer. For example, the touch protective layer SPAC may extend from the display area DA to the first non-display area NDA1 of the non-display area NDA, but the disclosure is not limited thereto.

For example, the touch protective layer SPAC may fill the trench TRC included in the touch buffer layer SBUF to contact the upper surfaces of the insulation layers BUF, GI, and ILD, but the disclosure is not limited thereto.

For example, the touch buffer layer SBUF may be an inorganic layer including an inorganic insulating material or an organic layer including an organic insulating material, the touch interlayer insulation layer may be an inorganic layer including an inorganic insulating material or an organic layer including an organic insulating material, and the touch protective layer SPAC may be an inorganic layer including an inorganic insulating material or an organic layer including an organic insulating material, but the disclosure is not limited thereto.

The display panel 110 according to embodiments of the disclosure may further include a polarization layer POL. For example, the polarization layer POL extends from the display area DA to the first non-display area NDA1 of the non-display area NDA and may be disposed on the touch protective layer SPAC, but the disclosure is not limited thereto. For example, the outer bank OUT_BNK may be positioned further outward than the polarization layer POL, but the disclosure is not limited thereto. For example, the polarization layer POL may be formed to overlap the trench TRC, but the disclosure is not limited thereto.

The display panel 110 according to embodiments of the disclosure may further include a micro-coating layer MCL. For example, the micro-coating layer MCL may be positioned outside the polarization layer POL in the first non-display area NDA1 and may overlap an outer portion of the touch protective layer SPAC. For example, the micro-coating layer MCL may overlap the trench TRC, but the disclosure is not limited thereto. As another example, the micro coating layer MCL may not overlap the trench TRC, but the disclosure is not limited thereto.

For example, the micro-coating layer MCL may prevent foreign objects or moisture introduced from the outside or prevent bending cracks or damage in the bending area BA formed around the first non-display area NDA1, but the disclosure is not limited thereto.

For example, the micro-coating layer MCL may be formed of a viscous polymer material. For example, the micro-coating layer MCL may prevent moisture penetration while protecting the signal line from external impact. For example, when the bending area BA is bent in a curved shape with a constant radius of curvature, a signal line may be positioned on the neutral plane of the micro-coating layer MCL where tensile and compressive forces become zero, but the disclosure is not limited thereto.

The display panel 110 according to embodiments of the disclosure may further include a dam DAM. For example, the dam DAM may further include at least one dam DAM positioned outside the first organic layer 342. For example, at least one of the first inorganic layer 341 and the second inorganic layer 343 may extend over the upper portion of the at least one dam to the outer periphery of the at least one dam DAM, but the disclosure is not limited thereto. For example, the trench TRC of the touch buffer layer SBUF may be positioned further outward than at least one dam DAM, but the disclosure is not limited thereto.

The display panel 110 according to embodiments of the disclosure may further include a first stopper STP1. For example, the first stopper STP1 is disposed on the outer portion of the bank 340 and may be positioned further outward than the first organic layer 342, but the disclosure is not limited thereto. For example, at least one of the first inorganic layer 341 and the second inorganic layer 343 may extend along the side surfaces of the insulation layers BUF, GI, and ILD past the upper and side surfaces of the first stopper STP1, but the disclosure is not limited thereto. For example, the first stopper STP1 may include an organic material, but the disclosure is not limited thereto. For example, the first stopper STP1 may be formed of the same material as the bank 340 and the outer bank OUT_BNK, but the disclosure is not limited thereto.

The display panel 110 according to embodiments of the disclosure may further include a second stopper STP2 disposed on the interlayer insulation layer ILD. For example, the second stopper STP2 may be positioned between the first stopper STP1 and at least one dam DAM, but the disclosure is not limited thereto. For example, the second stopper STP2 may include an organic material, but the disclosure is not limited thereto. For example, the second stopper STP2 may be formed of the same material as the bank 340 and the outer bank OUT_BNK, but the disclosure is not limited thereto.

The display panel 110 according to embodiments of the disclosure may further include a third stopper STP3 disposed on the interlayer insulation layer ILD. For example, the third stopper STP3 may be positioned between one of the first stopper STP1 and the second stopper STP2 and at least one dam DAM, but the disclosure is not limited thereto. For example, the third stopper STP3 may include an organic material, but the disclosure is not limited thereto. For example, the third stopper STP3 may be formed of the same material as the bank 340 and the outer bank OUT_BNK, but the disclosure is not limited thereto.

For example, the dam DAM may include a first dam DAMa, a second dam DAMb, and a third dam DAMc, but the disclosure is not limited thereto. For example, the first dam DAMa may be formed of the same material as the second planarization layer 332, but the disclosure is not limited thereto. For example, the second dam DAMb may be formed of the same material as the bank 340 and the outer bank OUT_BNK, but the disclosure is not limited thereto. For example, the third dam DAMc may be formed of the same material as the first stopper STP1, but the disclosure is not limited thereto.

Referring to FIG. 9, the display panel 110 according to embodiments of the disclosure having such a structure includes a trench TRC in the touch buffer layer SBUF, preventing ingress of moisture through the gaps caused by cracking or delamination in the touch buffer layer SBUF and hence reducing gate drain short (GDS) defects caused by moisture. However, when laser trimming of the micro-coating layer MCL is performed, there is a still chance of delamination or cracking at the end of the micro-coating layer MCL by the laser, which results in weak adhesion between the touch buffer layer SBUF and the substrate 111, causing delamination or cracking in the touch buffer layer SBUF.

According to embodiments of the disclosure, the display panel 110 of the display device 100 has a structure capable of reducing the influence on the touch buffer layer SBUF despite delamination or cracking at the end of the micro-coating layer MCL when a laser trimming line is formed in an edge area of the first non-display area NDA1.

Referring to FIG. 10, the first non-display area NDA1 of the display panel 110 according to embodiments of the disclosure may include a substrate 111, insulation layers BUF, GI and ILD, a planarization layer 330, an encapsulation layer 200, and a touch sensor layer, but embodiments of the disclosure are not limited thereto.

Referring to FIG. 10, the first non-display area NDA1 may further include a touch sensor layer on the encapsulation layer 200. For example, the touch sensor layer may include a touch buffer layer SBUF, a touch metal TM, and a touch protective layer SPAC, but the disclosure is not limited thereto.

The touch buffer layer SBUF may be disposed on the encapsulation layer 200. For example, the touch buffer layer SBUF may extend from the display area DA to the non-display area NDA and extend to the outer area of the encapsulation layer 200. For example, the touch buffer layer SBUF may cover at least one end of the first inorganic layer 341 and the second inorganic layer 343. For example, the touch buffer layer SBUF may be disposed to cover the outer surface of the outer bank OUT_BNK, and may contact the upper surface of the substrate 111 outside the outer bank OUT_BNK, but the disclosure is not limited thereto.

For example, the touch buffer layer SBUF may extend from the display area DA to the first non-display area NDA1 of the non-display area NDA, and may extend to the outer area of the encapsulation layer 200 and may include the trench TRC positioned in the outer area of the encapsulation layer 200, but the disclosure is not limited thereto. For example, by including a trench TRC in the touch buffer layer SBUF, when the touch buffer layer SBUF is delaminated or cracked, moisture may be prevented from flowing into it, thereby reducing gate drain short (GDS) occurrences due to moisture, but the disclosure is not limited thereto.

The touch sensor layer may further include a touch metal TM disposed on the touch buffer layer SBUF. For example, a plurality of touch metals TM may be formed. For example, the touch metal TM may include a touch metal layer including the touch metal TM to form a touch electrode.

For example, the touch metal TM may include a first touch metal TM1 and a second touch metal TM2, and may include a first touch metal layer where a plurality of first touch metals TM1 are disposed, and a second touch metal layer where a plurality of second touch metals TM2 are disposed. For example, the touch sensor layer may further include a touch interlayer insulation layer disposed between the first touch metal layer and the second touch metal layer, but the disclosure is not limited thereto.

For example, the touch buffer layer SBUF may be disposed between the encapsulation layer 200 and the touch metal layer. For example, a first touch metal layer may be disposed on the touch buffer layer SBUF, and a touch interlayer insulation layer may be disposed on the first touch metal layer, but the disclosure is not limited thereto.

The touch sensor layer may further include a touch protective layer SPAC disposed to cover the touch metal TM. For example, the touch protective layer SPAC may be disposed on the second touch metal layer. For example, the touch protective layer SPAC may extend from the display area DA to the first non-display area NDA1 of the non-display area NDA, but the disclosure is not limited thereto.

For example, the touch protective layer SPAC may fill the trench TRC included in the touch buffer layer SBUF to contact the upper surfaces of the insulation layers BUF, GI, and ILD, but the disclosure is not limited thereto. For example, the touch protective layer SPAC may cover the edge of the touch buffer layer SBUF and may contact the upper surface of the substrate 111 outside the edge of the touch buffer layer SBUF, but the disclosure is not limited thereto.

Referring to FIG. 11 illustrating a cross-sectional view taken along line B-B′ of the display panel 110 of FIG. 8 according to embodiments of the disclosure, there is disclosed a cross-sectional structure of a non-display area NDA including a first non-display area NDA1, a bending area BA, and a second non-display area NDA2. FIG. 11 may be an enlarged view to include the second non-display area NDA2 and the bending area BA outside the first non-display area NDA1 of the display panel 110 of FIG. 10. Descriptions substantially the same as those described in of the cross-sectional views of FIGS. 4 to 10 may be omitted.

Referring to FIG. 11, the non-display area NDA of the display panel 110 according to embodiments of the disclosure may include a substrate 111, insulation layers BUF, GI and ILD, a planarization layer 330, an encapsulation layer 200, a touch sensor layer, and a pad area, but embodiments of the disclosure are not limited thereto.

The bending area BA of the display panel 110 according to embodiments of the disclosure is an area where the substrate 111 is bent, and may be an area positioned between the first non-display area NDA1 and the second non-display area NDA2.

For example, the substrate 111 may include a bending area BA that is bent and folded, and the bending area BA may be bent to be positioned on a lower surface of an unfolded portion. The bending area BA is a partial area of the non-display area NDA, and may be positioned in the driving circuit area to which the data driving circuit is electrically connected and between the driving circuit area and the display area DA, but the disclosure is not limited thereto.

For example, in the display panel 110, as the flexible substrate 111 is used, and the bending area BA which is a portion to which the data driving circuit is connected is bent, a portion of the substrate 111 is folded backward. The folded bending area BA which is a portion which an image cannot be displayed is not visible from the front. Thus, by using the bending structure and wiring structure as illustrated in FIG. 8, it is possible to significantly reduce the bezel size of the display device 100—i.e., a narrow bezel design is possible which provides better aesthetic satisfaction.

For example, the bending area BA may overlap the trench TRC formed in the touch buffer layer SBUF, but the disclosure is not limited thereto. For example, in the bending area BA, the touch buffer layer SBUF may be disposed to cover the outer surface of the outer bank OUT_BNK, and may contact the upper surface of the substrate 111 outside the outer bank OUT_BNK, but the disclosure is not limited thereto. For example, in the bending area BA, the touch protective layer SPAC may cover the edge of the touch buffer layer SBUF and may contact the upper surface of the substrate 111 outside the edge of the touch buffer layer SBUF, but the disclosure is not limited thereto.

The second non-display area NDA2 of the display panel 110 according to embodiments of the disclosure may include a pad portion PAD where various pads are disposed, and may be an area farthest from the display area DA among the first non-display area NDA1, the bending area BA, and the second non-display area NDA2.

The pad portion PAD may be disposed on the insulation layers BUF, GI, and ILD of the second non-display area NDA2. Signal lines (e.g., display driving-related link lines, touch routing lines, etc.) may be electrically connected to the pad portion PAD, and the display driving circuit or the touch driving circuit may be bonded. The pad portion PAD may be positioned in the first pad area PA1. The pad portion PAD may be composed of a single electrode layer or multiple electrode layers. For example, when the pad portion PAD is composed of multiple electrode layers, the pad portion PAD may include a first pad PAD1 and a second pad PAD2 electrically connected to each other.

For example, a gate metal pattern GMP may be disposed to extend from the display area DA on the insulation layers BUF, GI, and ILD of the second non-display area NDA2. For example, the gate metal pattern GMP may be formed of the same material as the gate electrode material of the transistor in the display area DA. For example, the gate metal pattern GMP may be used as an electrode or signal line, but the disclosure is not limited thereto.

For example, the first pad PAD1 may be positioned in the same metal layer as the common voltage line VSSL. As another example, the first pad PAD1 may include the same material as the gate metal pattern GMP. However, the disclosure is not limited thereto.

For example, the second pad PAD2 may be disposed in a different metal layer than the first pad PAD1 and may include the same material as the second connection pattern CP2. Here, the second connection pattern CP2 may be disposed in the same metal layer as the connection electrode that electrically connects the source electrode or drain electrode of the transistor in the display area DA and the pixel electrode PE of the light emitting element ED. The pixel electrode PE may be disposed in the same metal layer as the first connection pattern CP1.

For example, a pad bank PAD_BNK may be further included on the second planarization layer 332. For example, the pad bank PAD_BNK may have an inclined surface, but the disclosure is not limited thereto. For example, the pad bank PAD_BNK may overlap the pad unit PAD, but the disclosure is not limited thereto. For example, the pad bank PAD_BNK may further include a micro-coating layer MCL, but the disclosure is not limited thereto.

For example, in the outer area of the second non-display area NDA2 (i.e., the outer area of B′), the second planarization layer 332, the second pad PAD2, and the pad bank PAD_BNK may be etched or omitted so that the IC Integrated Circuit may be connected, but the disclosure is not limited thereto.

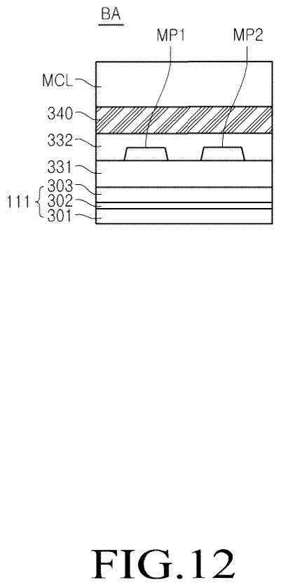

FIG. 12 is a view specifically illustrating a cross-sectional structure of the bending area BA of FIG. 11 according to embodiments of the disclosure.

Referring to FIG. 12, the bending area BA according to embodiments of the disclosure includes a substrate 111, a first planarization layer 331, a second planarization layer 332, a bank 340, and a micro-coating layer MCL.

The bending area BA is an area where the substrate 111 is bent, and may be an area positioned between the first non-display area NDA1 and the second non-display area NDA2.

The substrate 111 may be a flexible substrate capable of bending. The substrate 111 may be a single layer or multiple layers. When the substrate 111 includes multiple layers, the substrate 111 may include a first substrate 301, an intermediate substrate layer 302, and a second substrate 303. The intermediate substrate layer 302 may be positioned between the first substrate 301 and the second substrate 303.

For example, each of the first substrate 301 and the second substrate 303 may be a polyimide (PI) layer, but embodiments of the disclosure are not limited thereto. For example, the intermediate substrate layer 302 may be an inorganic insulation layer, but embodiments of the disclosure are not limited thereto. For example, when an electric charge is charged to the first substrate PI1 which is a polyimide layer, the intermediate substrate layer 302 may prevent the electric charge from affecting transistors disposed on the second substrate 303 through the second substrate 303 which is a polyimide layer.

Further, for example, the intermediate substrate layer 302 may prevent a moisture component from penetrating upward through the first substrate 301. For example, the intermediate substrate layer 302 may be formed of a single layer of silicon nitride (SiNx) or silicon oxide (SiOx) or multiple layers thereof, or may be formed of a double layer of silicon dioxide (SiO₂) and silicon nitride (SiNx), but is not limited thereto.

The first planarization layer 331 may be disposed on the substrate 111 of the bending area BA according to embodiments of the disclosure, and the second planarization layer 332 may be disposed on the first planarization layer 331.

For example, the second planarization layer 332 may further include a metal pattern. For example, the metal pattern may include a first metal pattern MP1 and a second metal pattern MP2. The first metal pattern MP1 and the second metal pattern MP2 may include the same first gate metal as the first gate electrode E1a of the first thin film transistor TFT1 included in the display area DA, but the disclosure is not limited thereto.

According to embodiments of the disclosure, a bank 340 may be included on the second planarization layer 332 of the bending area BA, and a micro-coating layer MCL may be further included on the bank 340, but the disclosure is not limited thereto.

A display device according to an embodiment of the disclosure may be described as follows.

A display device according to embodiments of the disclosure may comprise a substrate, a display area where an image is displayed, a non-display area positioned outside the display area, an insulation layer extending from the display area to the non-display area and disposed on the substrate, a light emitting element positioned in the display area and disposed on the insulation layer, an outer bank positioned in the non-display area and disposed to cover an end portion of the insulation layer, an encapsulation layer disposed on the light emitting element and extending from the display area to the non-display area, a touch buffer layer disposed on the encapsulation layer, and a touch metal disposed on the touch buffer layer. The touch buffer layer may extend from the display area to the non-display area and extends to an outer area of the encapsulation layer to have a trench positioned in the outer area of the encapsulation layer.

The touch buffer layer may be disposed to cover an outer surface of the outer bank.

The touch buffer layer may contact an upper surface of the substrate, outside the outer bank.

The display device may further comprise a touch protective layer disposed on the touch metal and extending from the display area to the non-display area. The touch protective layer may cover an edge of the touch buffer layer and contact an upper surface of the substrate, outside the touch buffer layer.

The touch protective layer may fill the trench to contact an upper surface of the insulation layer.

The display device may further comprise a polarization layer positioned to extend from the display area to the non-display area and disposed on the touch protective layer. The outer bank may be positioned further outward than the polarization layer.

The polarization layer may overlap the trench.

The display device may further comprise a micro-coating layer positioned outside the polarization layer in the non-display area. The micro-coating layer may overlap an outer portion of the touch protective layer.

The micro-coating layer may overlap the trench.

The micro-coating layer may not overlap the trench.

The micro-coating layer may include an organic material.

The encapsulation layer may include a first inorganic layer disposed on the light emitting element, a first organic layer disposed on the first inorganic layer and having an inclined surface, and a second inorganic layer disposed on the first organic layer. At least one of the first inorganic layer and the second inorganic layer may extend further outward than the first organic layer. The touch buffer layer may cover an end of at least one of the first inorganic layer and the second inorganic layer.

The display device may further comprise at least one dam positioned outside the first organic layer. At least one of the first inorganic layer and the second inorganic layer may extend over an upper portion of the at least one dam to an outside of the at least one dam. The touch buffer layer may extend to the outside of the at least one dam. The trench may be positioned further outward than the at least one dam.

The display device may further comprise a planarization layer disposed on the insulation layer, a bank disposed on the planarization layer, and a first stopper positioned over an outer portion of the bank and positioned further outward than the first organic layer. At least one of the first inorganic layer and the second inorganic layer may extend past an upper side and a side surface of the first stopper and along a side surface of the insulation layer.

The display device may further comprise a second stopper positioned between the first stopper and the at least one dam and disposed on the insulation layer.

The light emitting element may include a pixel electrode, an intermediate layer, and a common electrode. The display device may further comprise a common voltage line to which a common voltage may be applied, and a first connection pattern electrically connecting the common electrode and the common voltage line. The first connection pattern may include a same material as the pixel electrode. The common voltage line may be disposed on the insulation layer and overlaps at least a portion of a rear surface of the at least one dam.

The common voltage line may include a same material as a source electrode or a drain electrode of a transistor connected to the light emitting element.

The display device may further comprise a second connection pattern electrically connecting the first connection pattern and the common voltage line. The second connection pattern may include a same material as a connection electrode electrically connecting a source electrode or a drain electrode of a transistor connected to the light emitting element and a first electrode of the light emitting element.

A display device according to embodiments of the disclosure may comprise a substrate, a display area where an image is displayed, a non-display area positioned outside the display area, an insulation layer extending from the display area to the non-display area and disposed on the substrate, a light emitting element positioned in the display area and disposed on the insulation layer, an outer bank positioned in the non-display area and disposed to cover an end portion of the insulation layer, an encapsulation layer disposed on the light emitting element and extending from the display area to the non-display area, a touch buffer layer disposed on the encapsulation layer, a touch metal disposed on the touch buffer layer, and a touch protective layer disposed on the touch metal and extending from the display area to the non-display area. The touch protective layer may cover an edge of the touch buffer layer and contact an upper surface of the substrate, outside the touch buffer layer.

The touch buffer layer may extend from the display area to the non-display area and extends to an outer area of the encapsulation layer to have a trench positioned in the outer area of the encapsulation layer.

The above description has been presented to enable any person skilled in the art to make and use the technical idea of the disclosure, and has been provided in the context of a particular application and its requirements. Various modifications, additions and substitutions to the described embodiments will be readily apparent to those skilled in the art, and the general principles defined herein may be applied to other embodiments and applications without departing from the spirit and scope of the disclosure. The above description and the accompanying drawings provide an example of the technical idea of the disclosure for illustrative purposes only. That is, the disclosed embodiments are intended to illustrate the scope of the technical idea of the disclosure. The scope of protection of the present disclosure should be construed based on the following claims, and all technical features within the scope of equivalents thereof should be construed as being included within the scope of the present disclosure.

What is claimed:

1. A display device, comprising:
a substrate;
a display area where an image is displayed;
a non-display area positioned outside the display area;
an insulation layer extending from the display area to the non-display area and disposed on the substrate;
a light emitting element positioned in the display area and disposed on the insulation layer;
an outer bank positioned in the non-display area and disposed to cover an end portion of the insulation layer;
an encapsulation layer disposed on the light emitting element and extending from the display area to the non-display area;
a touch buffer layer disposed on the encapsulation layer; and
a touch metal disposed on the touch buffer layer,
wherein the touch buffer layer extends from the display area to the non-display area and extends to an outer area of the encapsulation layer to have a trench positioned in the outer area of the encapsulation layer.

2. The display device of claim 1, wherein the touch buffer layer is disposed to cover an outer surface of the outer bank.

3. The display device of claim 1, wherein the touch buffer layer contacts an upper surface of the substrate, outside the outer bank.

4. The display device of claim 1, further comprising a touch protective layer disposed on the touch metal and extending from the display area to the non-display area,
wherein the touch protective layer covers an edge of the touch buffer layer and contacts an upper surface of the substrate, outside the touch buffer layer.

5. The display device of claim 4, wherein the touch protective layer fills the trench to contact an upper surface of the insulation layer.

6. The display device of claim 4, further comprising a polarization layer positioned to extend from the display area to the non-display area and disposed on the touch protective layer,
wherein the outer bank is positioned further outward than the polarization layer.

7. The display device of claim 6, wherein the polarization layer overlaps the trench.

8. The display device of claim 6, further comprising a micro-coating layer positioned outside the polarization layer in the non-display area,
wherein the micro-coating layer overlaps an outer portion of the touch protective layer.

9. The display device of claim 8, wherein the micro-coating layer overlaps the trench.

10. The display device of claim 8, wherein the micro-coating layer does not overlap the trench.

11. The display device of claim 8, wherein the micro-coating layer includes an organic material.

12. The display device of claim 1, wherein the encapsulation layer includes:
a first inorganic layer disposed on the light emitting element;
a first organic layer disposed on the first inorganic layer and having an inclined surface; and
a second inorganic layer disposed on the first organic layer,
wherein at least one of the first inorganic layer and the second inorganic layer extends further outward than the first organic layer, and
wherein the touch buffer layer covers an end of at least one of the first inorganic layer and the second inorganic layer.

13. The display device of claim 12, further comprising at least one dam positioned outside the first organic layer,
wherein at least one of the first inorganic layer and the second inorganic layer extends over an upper portion of the at least one dam to an outside of the at least one dam,
wherein the touch buffer layer extends to the outside of the at least one dam, and
wherein the trench is positioned further outward than the at least one dam.

14. The display device of claim 13, further comprising:
a planarization layer disposed on the insulation layer;
a bank disposed on the planarization layer; and
a first stopper positioned over an outer portion of the bank and positioned further outward than the first organic layer,
wherein at least one of the first inorganic layer and the second inorganic layer extends past an upper side and a side surface of the first stopper and along a side surface of the insulation layer.

15. The display device of claim 14, further comprising a second stopper positioned between the first stopper and the at least one dam and disposed on the insulation layer.

16. The display device of claim 1, wherein the light emitting element includes a pixel electrode, an intermediate layer, and a common electrode, wherein the display device further comprises:
a common voltage line to which a common voltage is applied; and
a first connection pattern electrically connecting the common electrode and the common voltage line,
wherein the first connection pattern includes a same material as the pixel electrode, and
wherein the common voltage line is disposed on the insulation layer and overlaps at least a portion of a rear surface of the at least one dam.

17. The display device of claim 16, wherein the common voltage line includes a same material as a source electrode or a drain electrode of a transistor connected to the light emitting element.

18. The display device of claim 16, further comprising a second connection pattern electrically connecting the first connection pattern and the common voltage line,
wherein the second connection pattern includes a same material as a connection electrode electrically connecting a source electrode or a drain electrode of a transistor connected to the light emitting element and a first electrode of the light emitting element.

19. A display device, comprising:
a substrate;
a display area where an image is displayed;
a non-display area positioned outside the display area;
an insulation layer extending from the display area to the non-display area and disposed on the substrate;
a light emitting element positioned in the display area and disposed on the insulation layer;
an outer bank positioned in the non-display area and disposed to cover an end portion of the insulation layer;
an encapsulation layer disposed on the light emitting element and extending from the display area to the non-display area;
a touch buffer layer disposed on the encapsulation layer;
a touch metal disposed on the touch buffer layer; and
a touch protective layer disposed on the touch metal and extending from the display area to the non-display area,
wherein the touch protective layer covers an edge of the touch buffer layer and contacts an upper surface of the substrate, outside the touch buffer layer.

20. The display device of claim 19, wherein the touch buffer layer extends from the display area to the non-display area and extends to an outer area of the encapsulation layer to have a trench positioned in the outer area of the encapsulation layer.
